(19) United States
(12) Patent Application Publication
(10) Pub. No.: US 2026/0291640 A1
(43) Pub. Date: Sep. 24, 2026

(54) SUB-PAYLOAD BLOCK SPINAL ENCODING SCHEMES

(71) Applicant: QUALCOMM Incorporated, San Diego, CA (US)

(72) Inventors: Matan GUETTA, San Diego, CA (US); Peer BERGER, Hod Hasharon (IL); Gideon Shlomo KUTZ, Ramat Hasharon (IL)

(21) Appl. No.: 19/084,190

(22) Filed: Mar. 19, 2025

(51) Int. Cl. H04L 1/00

(52) U.S. Cl. CPC H04L 1/0033; H04L 1/003

(57) ABSTRACT

Various aspects of the present disclosure generally relate to wireless communication. In some aspects, a transmitter may segment a payload block into multiple sub-payload blocks. The transmitter may independently encode each sub-payload block, of the multiple sub-payload blocks, using a spinal code encoding scheme, resulting in multiple vectors of spinal symbols. The transmitter may combine the multiple vectors of spinal symbols, resulting in a transmission vector. The transmitter may transmit, to a receiver, a message indicating the transmission vector. Numerous other aspects are described.

### FIELD OF THE DISCLOSURE

Aspects of the present disclosure generally relate to wireless communication and specifically relate to techniques, apparatuses, and methods associated with sub-payload block spinal encoding schemes.

### DESCRIPTION OF THE RELATED TECHNOLOGY

Wireless communication systems are widely deployed to provide various services, which may involve carrying or supporting voice, text, other messaging, video, data, or other traffic. Typical wireless communication systems may employ multiple-access radio access technologies (RATs) capable of supporting communication among multiple wireless communication devices including user devices or other devices by sharing the available system resources (for example, time domain resources, frequency domain resources, spatial domain resources, or device transmit power, among other examples). Such multiple-access RATs are supported by technological advancements that have been adopted in various telecommunication standards, which define common protocols that enable different wireless communication devices to communicate on a local, municipal, national, regional, or global level. An example telecommunication standard is New Radio (NR). NR, which also may be referred to as 5G, is part of a continuous mobile broadband evolution promulgated by the Third Generation Partnership Project (3GPP). As the demand for connectivity continues to increase, further improvements in NR may be implemented, and other RATs, such as 6G and beyond, may be introduced to enable new applications and facilitate new use cases.

Wireless communication devices may communicate using messages encoded according to a channel coding algorithm. In some examples, a channel coding algorithm may be associated with spinal codes. Spinal codes involve a sequential application of a pseudo-random hash function to message bits to produce a sequence of coded symbols for transmission. Spinal code encoding ensures that two input messages that differ in even one bit lead to very different coded sequences after the point at which they differ, providing good resilience to noise and bit errors.

### SUMMARY

The systems, methods, and devices of this disclosure each have several innovative aspects, no single one of which is solely responsible for the desirable attributes disclosed herein.

Some aspects described herein relate to a method of wireless communication performed by a transmitter. The method may include segmenting a payload block into multiple sub-payload blocks. The method may include independently encoding each sub-payload block, of the multiple sub-payload blocks, using a spinal code encoding scheme, resulting in multiple vectors of spinal symbols. The method may include combining the multiple vectors of spinal symbols, resulting in a transmission vector. The method may include transmitting, to a receiver, a message indicating the transmission vector.

Some aspects described herein relate to a method of wireless communication performed by a receiver. The method may include receiving, from a transmitter, a message indicating a transmission vector, wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols. The method may include decoding the message, resulting in information bits associated with the payload block.

Some aspects described herein relate to a transmitter. The transmitter may include a processing system. The processing system may include one or more processors and one or more code-storing memories coupled with the one or more processors. The processing system may be configured to cause the transmitter to segment a payload block into multiple sub-payload blocks. The processing system may be configured to cause the transmitter to independently encode each sub-payload block, of the multiple sub-payload blocks, using a spinal code encoding scheme, resulting in multiple vectors of spinal symbols. The processing system may be configured to cause the transmitter to combine the multiple vectors of spinal symbols, resulting in a transmission vector. The processing system may be configured to cause the transmitter to transmit, to a receiver, a message indicating the transmission vector.

Some aspects described herein relate to a receiver. The receiver may include a processing system. The processing system may include one or more processors and one or more code-storing memories coupled with the one or more processors. The processing system may be configured to cause the receiver to receive, from a transmitter, a message indicating a transmission vector, wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols. The processing system may be configured to cause the receiver to decode the message, resulting in information bits associated with the payload block.

Some aspects described herein relate to a non-transitory computer-readable medium that stores a set of instructions for wireless communication by a transmitter. The set of instructions, when executed by one or more processors of the transmitter, may cause the transmitter to segment a payload block into multiple sub-payload blocks. The set of instructions, when executed by one or more processors of the transmitter, may cause the transmitter to independently encode each sub-payload block, of the multiple sub-payload blocks, using a spinal code encoding scheme, resulting in multiple vectors of spinal symbols. The set of instructions, when executed by one or more processors of the transmitter, may cause the transmitter to combine the multiple vectors of spinal symbols, resulting in a transmission vector. The set of instructions, when executed by one or more processors of the transmitter, may cause the transmitter to transmit, to a receiver, a message indicating the transmission vector.

Some aspects described herein relate to a non-transitory computer-readable medium that stores a set of instructions for wireless communication by a receiver. The set of instructions, when executed by one or more processors of the receiver, may cause the receiver to receive, from a transmitter, a message indicating a transmission vector, wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols. The set of instructions, when executed by one or more processors of the receiver, may cause the receiver to decode the message, resulting in information bits associated with the payload block.

Some aspects described herein relate to an apparatus for wireless communication. The apparatus may include means for segmenting a payload block into multiple sub-payload blocks. The apparatus may include means for independently encoding each sub-payload block, of the multiple sub-payload blocks, using a spinal code encoding scheme, resulting in multiple vectors of spinal symbols. The apparatus may include means for combining the multiple vectors of spinal symbols, resulting in a transmission vector. The apparatus may include means for transmitting, to a receiver, a message indicating the transmission vector.

Some aspects described herein relate to an apparatus for wireless communication. The apparatus may include means for receiving, from a transmitter, a message indicating a transmission vector, wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols. The apparatus may include means for decoding the message, resulting in information bits associated with the payload block.

Aspects of the present disclosure may generally be implemented by or as a method, apparatus, system, computer program product, non-transitory computer-readable medium, user equipment, network node, wireless communication device, or processing system as substantially described in the Detailed Description with reference to, and as illustrated by, the accompanying drawings. Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 is a diagram illustrating an example of a wireless communication network.

FIG. 2 is a diagram illustrating an example disaggregated network node architecture.

FIG. 3 is a diagram illustrating an example associated with encoding of spinal codes.

FIGS. 4A-4B are diagrams illustrating examples associated with puncturing schemes for spinal codes.

FIGS. 5A-5E are diagrams of examples associated with sub-payload block spinal code encoding schemes.

FIG. 6 is a diagram illustrating an example process performed, for example, at a transmitter or an apparatus of a transmitter.

FIG. 7 is a diagram illustrating an example process performed, for example, at a receiver or an apparatus of a receiver.

FIG. 8 is a diagram of an example apparatus for wireless communication.

FIG. 9 is a diagram of another example apparatus for wireless communication.

### DETAILED DESCRIPTION

Binary coding schemes involve separately encoding and modulating a communication. Various types of binary codes are used in telecommunications. For example, New Radio (NR) physical downlink shared channel (PDSCH) uses binary low-density parity-check (LDPC) code, NR physical downlink control channel (PDCCH) uses binary polar code, Long Term Evolution (LTE) PDSCH uses binary turbo code, LTE PDCCH uses binary convolution code, and so forth. However, binary codes can be less spectrally efficient than non-binary coding schemes, particularly for short block lengths. Non-binary codes, which involve jointly encoding and modulating a communication, offer an attractive tradeoff between performance and complexity.

Spinal codes are a class of Euclidean codes, which are typically rateless codes (but that can be used as a fixed-rate code) that can handle time-varying channel conditions without requiring explicit bit rate selection. Spinal codes, when used as rateless codes, involve transmission at a higher rate than a channel can sustain followed by iterative retransmission of information bits to lower the effective rate until a decoding success occurs (for example, until the receiver transmits an acknowledgment (ACK) or a negative acknowledgment (NACK)). More specifically, the transmitter may perform the encoding once, and the channel rate may be changed based at least in part on the total quantity of channel uses (for example, a total quantity of times a communication channel is utilized to transmit information, which, in some examples, corresponds to a total quantity of resource elements (REs)).

A spinal code encoder, which may operate on multiple “spines,” may be considered a sequential encoder, because an output of each spine may be used as an input for the next spine. More particularly, a spinal code encoder may use a hash function and multiple v-bit states, where the v-bit state of each spine is used a seed to the hash function for the next spine. More particularly, a first v-bit state, which may be a result of inputting a first block of message bits into a hash function (e.g., inputting a first set of k bits into the hash function), may be used as a seed for the hash function in a second spine. Similarly, a second v-bit state, which may be a result of inputting a second block of message bits into the hash function (e.g., inputting a second set of k bits into the hash function), may be used as a seed for the hash function in the third spine, and so forth. In this regard, the last spine is a function of all previous spines (e.g., the spines associated with the first v-bit state through a next-to-last v-bit state). Put another way, the result of the hash function in the last spine is a result of a last block of message bits as well as all previous blocks of message bits.

In this regard, the spinal code encoding scheme may be relatively slow as compared to other encoding schemes, because the sequential encoder may not work in parallel on each block of message bits, but instead, for each block of message bits, the sequential encoder may need to wait for a previous v-bit state to use as a seed for the hash function for that block of message bits. Accordingly, for large code blocks (CBs) (e.g., packets processed by the channel coding algorithm) or similar payload blocks, encoding and decoding data using a spinal code encoding scheme may take a long time or may be impractical for certain applications. For example, in some wireless communication systems (e.g., 5G systems), a maximum CB size may be 8448 bits. Encoding the 8448 bits using a sequential decoder, such as an encoder associated with a spinal code encoding scheme, may be relatively slow, resulting in high latency and otherwise inefficient usage of network resources.

Various aspects relate generally to spinal coding schemes for wireless communications. Some aspects more specifically relate to sub-payload block (e.g., sub-CB or sub-transport block (TB)) spinal code encoding schemes. In some aspects, a transmitter (e.g., a network node or a user equipment (UE), among other examples) may segment a payload block (e.g., a CB, such as an 8448-bit CB, among other examples) into multiple sub-payload blocks (e.g., multiple sub-CBs or multiple sub-TBs). In some aspects, the payload block may be associated with information bits and cyclic redundancy check (CRC) bits, such as a first set of CRC bits associated with a first-stage-decoding-check operation and a second set of CRC bits associated with a second-stage-decoding-check operation. In such aspects, the transmitter may segment a concatenation of the information bits and the CRC bits into the sub-payload blocks. Moreover, in some aspects, the transmitter may copy a portion of information bits from a beginning portion of each sub-payload block (sometimes referred to herein as tail-biting bits) and concatenate the copied portion of information bits to an end portion of that sub-payload block, which may be used during a decoding process of that sub-payload block (e.g., which may be used during a tail-biting check process). The transmitter may independently encode each sub-payload block using a spinal code encoding scheme, resulting in multiple vectors of spinal symbols. The transmitter may combine the multiple vectors of spinal symbols into a transmission vectors and may thus transmit, to a receiver (e.g., a network node or a UE, among other examples), a message indicating the transmission vector.

The receiver may decode the message to determine the information bits associated with the transmission vector or the payload block. In some aspects, the receiver may decode the message by determining, for each sub-payload block, one or more sub-payload-block hypotheses. Moreover, in some aspects, the receiver may determine a subset of the one or more sub-payload-block hypotheses that pass a check associated with the copied portion of information bits for that sub-payload block (e.g., the receiver may determine a subset of the one or more sub-payload-block hypotheses that pass a tail-biting check). The receiver may decode the message by determining multiple payload-block hypotheses (with each payload-load hypothesis being a concatenation of selected sub-payload-block hypotheses) and by performing one or more CRC checks on the payload-block hypotheses to estimate the payload block information bits.

Particular aspects of the subject matter described in this disclosure can be implemented to realize one or more of the following potential advantages. In some examples, due to a rateless property of some spinal codes (for example, a property associated with the spinal code enabling infinite generation of encoded symbols or continuous transmission of a message until the message is decoded), the sub-payload block spinal code encoding schemes described herein may be better suited for unpredictable or varying channel conditions as compared to fixed-rate LDPC or polar codes, resulting in fewer communication errors in varying channels and thus less computing, power, or network resource consumption than otherwise required for correcting communication errors. Additionally or alternatively, sub-payload block spinal code encoding schemes may be equipped to handle a variety of channels without requiring specific channel state information (CSI), enabling high performance across multiple channel scenarios, further resulting in fewer communication errors and thus less computing, power, or network resource consumption than otherwise required for correcting communication errors.

In some other examples, because spinal codes may be associated with a simpler encoding process as compared to LDPC or polar codes, the described techniques can be used to decrease an encoding complexity at a transmitter, thereby reducing power, computing, or other resource consumption at the transmitter (for example, a network node or a UE, among other examples). Additionally or alternatively, because spinal codes may require reduced feedback from a receiver as compared to LDPC codes or polar codes (for example, due to the rateless nature of some uses of spinal codes, among other examples), the described techniques can be used to decrease power, computing, or network resource consumption otherwise associated with feedback communications sent from a receiver to a transmitter.

In some examples, by segmenting a payload block into sub-payload blocks and independently encoding each sub-payload block using a spinal code encoding scheme, the aspects and techniques described herein may enable parallel encoding and decoding of large chunks of data. In such examples, the parallel encoding and decoding of large chunks of data may reduce latency as compared to spinal code encoding schemes that sequentially encode large CBs or similar payload blocks, thus resulting in increased throughput and otherwise more efficient usage of network resources. Moreover, spinal codes may perform well for short payload blocks, and thus reducing the payload block length may not degrade the spinal code's performance and may even improve the spinal code's performance. More particularly, shortening the payload block length may result in an improved performance (e.g., a performance of a spinal code encoding scheme using sub-payload blocks may be better than a performance of a spinal code encoding scheme using payload blocks) because a probability of exceeding a maximum allowed hypotheses (e.g., B, described in more detail below) may be reduced, among other examples.

5G NR may support enhanced mobile broadband (eMBB) access, Internet of Things (IoT) networks or reduced capability (RedCap) device deployments, ultra-reliable low-latency communication (URLLC) applications, or massive machine-type communication (mMTC), among other examples. To support these and other target verticals, a wireless communication system may be designed to implement a modularized functional infrastructure, a disaggregated and service-based network architecture, network function virtualization, network slicing, multi-access edge computing, millimeter wave (mmWave) technologies including massive multiple-input multiple-output (MIMO), beamforming, IoT device or RedCap device connectivity and management, industrial connectivity, licensed and unlicensed spectrum access, sidelink and other device-to-device direct communication (for example, cellular vehicle-to-everything (CV2X) communication), frequency spectrum expansion, overlapping spectrum use, small cell deployments, non-terrestrial network (NTN) deployments, device aggregation, advanced duplex communication (for example, sub-band full-duplex (SBFD)), multiple-subscriber implementations, high-precision positioning, radio frequency (RF) sensing, network energy savings (NES), low-power signaling and radios, or artificial intelligence or machine learning (AI/ML), among other examples.

The foregoing and other technological improvements may support use cases, such as wireless fronthauls, wireless midhauls, wireless backhauls, wireless data centers, extended reality (XR) and metaverse applications, meta services for supporting vehicle connectivity, holographic and mixed reality communication, autonomous and collaborative robots, vehicle platooning and cooperative maneuvering, sensing networks, gesture monitoring, human-brain interfacing, digital twin applications, asset management, and universal coverage applications using non-terrestrial or aerial platforms, among other examples.

The methods, operations, apparatuses, and techniques described herein may enable one or more of the foregoing technologies or new technologies or support one or more of the foregoing use cases or new use cases.

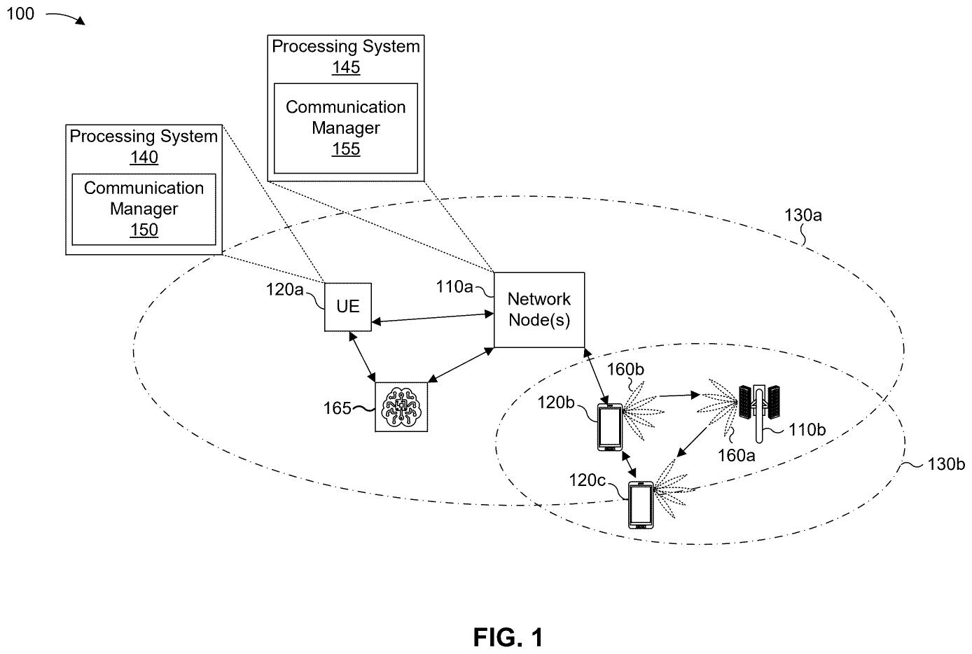

FIG. 1 is a diagram illustrating an example of a wireless communication network 100. The wireless communication network 100 may be or may include elements of a 5G network or a 6G network, among other examples. The wireless communication network 100 may include multiple network nodes 110. For example, in FIG. 1, the wireless communication network 100 includes multiple network nodes 110, including a network node 110a and a network node 110b (each of which also may be referred to herein simply as a “network node 110”). The network nodes 110 may support communications with multiple UEs 120. For example, in FIG. 1, the network nodes 110 support communication with a UE 120a, a UE 120b, and a UE 120c (each of which also may be referred to herein simply as a “UE 120”). In some examples, a UE 120 also may communicate with other UEs 120 and a network node 110 also may communicate with a core network and with other network nodes 110.

The network nodes 110 and the UEs 120 of the wireless communication network 100 communicate using the electromagnetic spectrum, which may be subdivided into various licensed or unlicensed operating bands, frequency ranges, component carriers, or channels that define associated frequencies available for communications. In some examples, each of the network nodes 110 and the UEs 120 may communicate using one or multiple component carriers in one or more operating bands or ranges. Typically, various operating bands are defined as frequency range designations FR1 (410 MHz through 7.125 GHZ), FR2 (24.25 GHZ through 52.6 GHz), FR3 (7.125 GHz through 24.25 GHZ), FR4a or FR4-1 (52.6 GHz through 71 GHz), FR4 (52.6 GHz through 114.25 GHZ), and FR5 (114.25 GHz through 300 GHz). Although a portion of FR1 is greater than 6 GHZ, FR1 is often referred to (interchangeably) as a “sub-6 GHz” band in some documents and articles. Similarly, FR2 is often referred to (interchangeably) as a “millimeter wave” band in some documents and articles.

A network node 110 or a UE 120 may include one or more devices, components, or systems that enable communication with other devices, components, or systems of the wireless communication network 100. For example, a UE 120 and a network node 110 may each include one or more chips, system-on-chips (SoCs), chipsets, packages, or devices that individually or collectively constitute or comprise a processing system. As shown in FIG. 1, each UE 120 includes a processing system 140 and each network node 110 includes a processing system 145. A processing system (for example, the processing system 140 or the processing system 145) includes processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), or digital signal processors (DSPs)), processing blocks, application-specific integrated circuits (ASICs), programmable logic devices (PLDs), or other discrete gate or transistor logic or circuitry (any one or more of which may be generally referred to herein individually as a “processor” or collectively as “the processor” or “the processor circuitry”). Such processors may be individually or collectively configurable or configured to perform various functions or operations described herein. A group of processors collectively configurable or configured to perform a set of functions may include a first processor configurable or configured to perform a first function of the set and a second processor configurable or configured to perform a second function of the set. In some other examples, each of a group of processors may be configurable or configured to perform a same set of functions.

The processing system 140 and the processing system 145 may each include memory circuitry in the form of one or multiple memory devices, memory blocks, memory elements, or other discrete gate or transistor logic or circuitry, each of which may include or implement tangible storage media, such as random-access memory, or read-only memory, or combinations thereof (any one or more of which may be generally referred to herein individually as a “memory” or collectively as “the memory” or “the memory circuitry”). One or more of the memories may be coupled (for example, operatively coupled, communicatively coupled, electronically coupled, or electrically coupled) with one or more of the processors. One or more of the memories may individually or collectively store processor-executable code or instructions (such as software) (for example, which may be referred to as “one or more code-storing memories” or “code-storing memory circuitry”). For example, “code-storing memory” or “code-storing memory circuitry” refers to memory (or memory circuitry) that is configured to store processor-executable code or instructions. The processor-executable code or instructions, when executed by one or more of the processors, may configure one or more of the processors (or processing circuitry) to perform various functions or operations described herein. Additionally, or alternatively, in some examples, one or more of the processors may be configured to perform various functions or operations described herein without requiring configuration by software. Software shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise.

The processing system 140 and the processing system 145 may each include or be coupled with one or more modems (such as a cellular (for example, a 5G or 6G compliant) modem). In some examples, one or more processors of the processing system 140 or the processing system 145 may include or implement one or more of the modems. The processing system 140 and the processing system 145 also may include or be coupled with multiple radios (collectively “the radio”), multiple RF chains, or multiple transceivers, each of which may in turn be coupled with one or more of multiple antennas. In some examples, one or more processors of the processing system 140 or the processing system 145 may include or implement one or more of the radios, RF chains, or transceivers. An RF chain may include one or more filters, mixers, oscillators, amplifiers, analog-to-digital converters (ADCs), or other devices that convert between an analog signal (such as for transmission or reception via an air interface) and a digital signal (such as for processing by the processing system 140 or by the processing system 145).

A network node 110 and a UE 120 may each include one or multiple antennas or antenna arrays. Typical network nodes 110 and UEs 120 may include multiple antennas, which may be organized or structured into one or more antenna panels, one or more antenna groups, one or more sets of antenna elements, or one or more antenna arrays, among other examples. As used herein, the term “antenna” can refer to one or more antennas, one or more antenna panels, one or more antenna groups, one or more sets of antenna elements, or one or more antenna arrays. The term “antenna panel” can refer to a group of antennas (such as antenna elements) arranged in an array or panel, which may facilitate beamforming by manipulating parameters associated with the group of antennas. The term “antenna module” may refer to circuitry including one or more antennas as well as one or more other components (such as filters, amplifiers, or processors) associated with integrating the antenna module into a wireless communication device, such as the network node 110 and the UE 120.

A network node 110 may be, may include, or also may be referred to as an NR network node, a 5G network node, a 6G network node, a Node B, a gNB, an access point (AP), a transmission reception point (TRP), a network entity, a network element, a network equipment, or another type of device, component, or system included in a radio access network (RAN). In various deployments, a network node 110 may be implemented as a single physical node (for example, a single physical structure) or may be implemented as two or more physical nodes (for example, two or more distinct physical structures). For example, a network node 110 may be a device or system that implements a part of a radio protocol stack, a device or system that implements a full radio protocol stack (such as a full gNB protocol stack), or a collection of devices or systems that collectively implement the full radio protocol stack. For example, and as shown, a network node 110 may be an aggregated network node having an aggregated architecture, meaning that the network node 110 may implement a full radio protocol stack that is physically and logically integrated within a single physical structure in the wireless communication network 100. For example, an aggregated network node 110 may include a single standalone base station or a single TRP that operates with a full radio protocol stack to enable or facilitate communication between a UE 120 and a core network of the wireless communication network 100.

Alternatively, and as also shown, a network node 110 may be a disaggregated network node 110 (sometimes referred to as a disaggregated base station), having a disaggregated architecture, meaning that the network node 110 may operate with a radio protocol stack that is physically distributed or logically distributed among two or more nodes in the same geographic location or in different geographic locations. In some deployments, disaggregated network nodes 110 may be used in an integrated access and backhaul (IAB) network, in an open radio access network (O-RAN) (such as a network configuration in compliance with the O-RAN Alliance), or in a virtualized radio access network (vRAN), also known as a cloud radio access network (C-RAN), to facilitate scaling by separating network functionality into multiple units or modules that can be individually deployed.

The disaggregated network nodes 110 of the wireless communication network 100 may include one or more central units (CUs), one or more distributed units (DUs), and one or more radio units (RUs). A CU may host one or more higher layers, such as a radio resource control (RRC) layer, a packet data convergence protocol (PDCP) layer, and a service data adaptation protocol (SDAP) layer, among other examples. A DU may host one or more of a radio link control (RLC) layer, a medium access control (MAC) layer, or one or more higher physical (PHY) layers depending, at least in part, on a functional split, such as a functional split defined by the 3GPP. In some examples, a DU also may host a lower PHY layer that is configured to perform functions, such as a fast Fourier transform (FFT), an inverse FFT (IFFT), beamforming, or physical random access channel (PRACH) extraction and filtering, among other examples. An RU may perform RF processing functions or lower PHY layer functions, such as an FFT, an IFFT, beamforming, or PRACH extraction and filtering, among other examples, according to a functional split, such as a lower layer split (LLS). In such an architecture, each RU can be operated to handle over the air (OTA) communication with one or more UEs 120. In some examples, a single network node 110 may include a combination of one or more CUs, one or more DUs, or one or more RUs. In some examples, a CU, a DU, or an RU may be implemented as a virtual unit, such as a virtual central unit (VCU), a virtual distributed unit (VDU), or a virtual radio unit (VRU), among other examples, which may be implemented as a virtual network function, such as in a cloud deployment.

In some examples, the wireless communication network 100 may be a heterogeneous network that includes network nodes 110 of various types. Different types of network nodes 110 may generally operate on the same or different operating bands, transmit at different power levels, or serve different coverage areas, each of which may be referred to as or associated with a particular cell 130 (for example, a cell 130a and a cell 130b).

The UEs 120 may be physically dispersed throughout the coverage area of the wireless communication network 100, and each UE 120 may be stationary or mobile. A UE 120 may be, may include, or also may be referred to as an access terminal, a mobile station, a client device, or a subscriber unit. A UE 120 may be, include, or be coupled with a cellular phone (for example, a smart phone), a personal digital assistant (PDA), a wireless modem, a wireless communication device, a handheld device, a laptop computer, a cordless phone, a wireless local loop (WLL) station, a tablet, a camera, a netbook, a smartbook, an ultrabook, a medical device, a biometric device, a wearable device (for example, a smart watch, smart clothing, smart glasses, a smart wristband, or smart jewelry), a gaming device, an entertainment device (for example, a music device, a video device, or a satellite radio), an XR device, a vehicular component or sensor, a smart meter or sensor, industrial manufacturing equipment, a Global Navigation Satellite System (GNSS) device (such as a Global Positioning System device or another type of positioning device), an artificially intelligent robot or other device implementing artificial intelligence, a UE function of a network node, or any other suitable device or function that may communicate in the wireless communication network 100.

Some UEs 120 may be classified according to different categories in association with different complexities or different capabilities. UEs 120 in a first category may be associated with relatively low complexity or cost such as NB-IoT devices or eMTC UEs. UEs 120 in a second category may include higher complexity or cost devices, such as mission-critical IoT devices, baseline UEs, high-tier UEs, advanced UEs, full-capability UEs, or premium UEs that are capable of URLLC, eMBB, or precise positioning in the wireless communication network 100. A third category of UEs 120 may have mid-tier complexity or capabilities (for example, capabilities between that of the UEs 120 of the first category and the UEs 120 of the second category). A UE 120 of the third category may be referred to as a reduced capability UE (“RedCap UE”), a mid-tier UE, an NR-Light UE, or an NR-Lite UE, among other examples.

In some examples, a network node 110 may be, may include, or may operate as an RU, a TRP, or a base station that communicates with one or more UEs 120 via a radio access link (which may be referred to as a “Uu” link). The radio access link may include a downlink and an uplink. “Downlink” (or “DL”) refers to a communication direction from a network node 110 to a UE 120, and “uplink” (or “UL”) refers to a communication direction from a UE 120 to a network node 110. Downlink and uplink resources may include time domain resources (for example, frames, subframes, slots, and symbols), frequency domain resources (for example, frequency bands, component carriers (CCs), subcarriers, resource blocks, and resource elements), and spatial domain resources (for example, particular transmit directions or beams).

Frequency domain resources may be subdivided into bandwidth parts (BWPs). A BWP may be a block of frequency domain resources (for example, a continuous set of resource blocks (RBs) within a full component carrier bandwidth) that may be configured at a UE-specific level. A UE 120 may be configured with both an uplink BWP and a downlink BWP (which may be the same or different). Each BWP may be associated with its own numerology (indicating a sub-carrier spacing (SCS) and cyclic prefix (CP)). A BWP may be dynamically configured or activated (for example, by a network node 110 transmitting a downlink control information (DCI) configuration to the one or more UEs 120) or reconfigured (for example, in real-time or near-real-time) according to changing network conditions in the wireless communication network 100 or specific requirements of one or more UEs 120. An active BWP defines the operating bandwidth of the UE 120 within the operating bandwidth of the serving cell.

As used herein, a downlink signal may be or include a reference signal, control information, or data. For example, downlink reference signals include a primary synchronization signal (PSS), a secondary SS (SSS), an SS block (SSB) (for example, that includes a PSS, an SSS, and a physical broadcast channel (PBCH)), a demodulation reference signal (DMRS), a phase tracking reference signal (PTRS), a tracking reference signal (TRS), and a channel state information (CSI) reference signal (CSI-RS), among other examples. A downlink signal carrying control information or data may be transmitted via a downlink channel. Downlink channels may include one or more control channels for transmitting control information and one or more data channels for transmitting data. Downlink reference signals may be transmitted in addition to, or multiplexed with, downlink control channel communications or downlink data channel communications. A downlink control channel may be specifically used to transmit DCI from a network node 110 to a UE 120. DCI generally contains the information the UE 120 needs to identify RBs in a subsequent subframe and how to decode them, including a modulation and coding scheme (MCS) or redundancy version parameters. Different DCI formats carry different information, such as scheduling information in the form of downlink or uplink grants, slot format indicators (SFIs), preemption indicators (PIs), transmit power control (TPC) commands, hybrid automatic repeat request (HARQ) information, new data indicators (NDIs), among other examples. A downlink data channel may be used to transmit downlink data (for example, user data associated with a UE 120) from a network node 110 to a UE 120. Downlink control channels may include PDCCHs, and downlink data channels may include PDSCHs. Control information or data communications may be transmitted on a PDCCH and PDSCH, respectively. For example, a PDCCH can carry DCI, while a PDSCH can carry a MAC control element (MAC-CE), an RRC message, or user data, among other examples. Each PDSCH may carry one or more TBs of data.

As used herein, an uplink signal may include a reference signal, control information, or data. For example, uplink reference signals include a sounding reference signal (SRS), a PTRS, and a DMRS, among other examples. An uplink signal carrying control information or data may be transmitted via an uplink channel. An uplink channel may include one or more control channels for transmitting control information and one or more data channels for transmitting data. Uplink reference signals may be transmitted in addition to, or multiplexed with, uplink control channel communications or uplink data channel communications. An uplink control channel may be specifically used to transmit uplink control information (UCI) from a UE 120 to a network node 110. An uplink data channel may be used to transmit uplink data (for example, user data associated with a UE 120) from a UE 120 to a network node 110. Uplink control channels may include physical uplink control channels (PUCCHs), and uplink data channels may include physical uplink shared channels (PUSCHs). Control information or data communications may be transmitted on a PUCCH and PUSCH, respectively. For example, a PUCCH can carry UCI, while a PUSCH can carry a MAC-CE, an RRC message, or user data, among other examples. UCI can include a scheduling request (SR), HARQ feedback information (for example, a HARQ ACK indication or a HARQ NACK indication), uplink power control information (for example, an uplink TPC parameter), or CSI, among other examples. CSI can include a channel quality indicator (CQI) (indicative of downlink channel conditions to facilitate selection of transmission parameters, such as an MCS, by a network node 110), a precoding matrix indicator (PMI), a CSI-RS resource indicator (CRI) (for example, indicative of a beam used to transmit a CSI-RS), an SS/PBCH resource block indicator (SSBRI) (for example, indicative of a beam used to transmit an SSB), a layer indicator (LI), a rank indicator (RI), or measurement information (for example, a layer 1 (L1)-reference signal received power (RSRP) parameter, a received signal strength indicator (RSSI) parameter, a reference signal received quality (RSRQ) parameter, among other examples) which can be used for beam management, among other examples. Each PUSCH may carry one or more TBs of data.

The information (for example, data, control information, or reference signal information) transmitted by a network node 110 to a UE 120, or vice versa, may be represented as a sequence of binary bits that are mapped (for example, modulated) to an analog signal waveform (for example, a discrete Fourier transform (DFT)-spread-orthogonal frequency division multiplexing (OFDM) (DFT-s-OFDM) waveform or a CP-OFDM waveform) that is transmitted by the network node 110 or UE 120 over a wireless communication channel. In some examples, the network node 110 or the UE 120 (for example, using the processing system 145 or the processing system 140, respectively) may select an MCS (for example, an order of quadrature amplitude modulation (QAM), such as 64-QAM, 128-QAM, or 256-QAM, among other examples) for a downlink signal or an uplink signal. For example, the network node 110 may select an MCS for a downlink signal in accordance with UCI received from the UE 120 or may transmit, to the UE 120, an indication of an MCS to be applied for an uplink signal.

A network node 110 or a UE 120 (such as by using the processing system 145 or the processing system 140, respectively, or one or more coupled modems) may perform signal processing on the information (such as filtering, amplification, modulation, digital-to-analog conversion, an IFFT operation, multiplexing, interleaving, mapping, or encoding, among other examples) to generate a processed signal in accordance with the selected MCS. In some examples, the network node 110 or the UE 120 (for example, using the processing system 145 or the processing system 140, respectively, or one or more coupled encoders or modems) may perform a channel coding operation or a forward error correction (FEC) operation to control errors in transmitted information. For example, the network node 110 or the UE 120 may perform an encoding operation to generate encoded information (such as by selectively introducing redundancy into the information, typically using an error correction code (ECC), such as a polar code or a LDPC code). The network node 110 or the UE 120 (for example, using the processing system 145 or one or more modems) may further perform spatial processing (for example, precoding) on the encoded information to generate one or more processed or precoded signals for downlink or uplink transmission, respectively. In some examples, the network node 110a or the UE 120a may perform codebook-based precoding or non-codebook-based precoding. Codebook-based precoding may involve selecting a precoder (for example, a precoding matrix) using a codebook. For example, the network node 110a may provide precoding information indicating which precoder, defined by the codebook, is to be used by the UE 120a. Non-codebook-based precoding may involve selecting or deriving a precoder based on, or otherwise associated with, one or more downlink or uplink signal measurements. The network node 110a or the UE 120a may transmit the processed downlink or uplink signals, respectively, via one or more antennas.

The network node 110a or the UE 120a may receive uplink signals or downlink signals, respectively, via one or more antennas. The network node 110a or the UE 120a (for example, using the processing system 145 or the processing system 140, respectively, or one or more coupled modems) may perform signal processing (for example, in accordance with the MCS) on the received uplink or downlink signals, respectively (such as filtering, amplification, demodulation, analog-to-digital conversion, an FFT operation, demultiplexing, deinterleaving, de-mapping, equalization, interference cancellation, or decoding, among other examples), to map the received signal(s) to a sequence of binary bits (for example, received information) that estimates the information transmitted by the network node 110 or the UE 120 via the downlink or uplink signals. The network node 110a or the UE 120a (for example, using the processing system 145 or the processing system 140, respectively, or a coupled decoder or one or more modems) may decode the received information (such as by using an ECC, a decoding operation, or an FEC operation) to detect errors or correct bit errors in the received information to generate decoded information. The decoded information may estimate the information transmitted via the downlink or uplink signals.

In some examples, a UE 120 and a network node 110 may perform MIMO communication. MIMO communication generally refers to transmitting or receiving multiple signals (such as multiple layers or multiple data streams) simultaneously over the same time and frequency resources. A network node 110 or a UE 120 may communicate using single-user MIMO or multi-user MIMO (MU-MIMO), the latter of which being used by a network node 110 to simultaneously transmit signals to multiple UEs 120. MIMO techniques may involve spatial multiplexing (multi-layer transmission) or beamforming. To implement beamforming, the amplitudes or phases of signals transmitted via antenna elements may be modulated and shifted relative to each other (such as by manipulating a phase shift, a phase offset, or an amplitude) to generate one or more beams. For example, a network node 110 may generate one or more beams 160a, and a UE 120 may generate one or more beams 160b. The term “beam” may refer to a directional transmission of a wireless signal toward a receiving device or otherwise in a desired direction, a directional reception of a wireless signal from a transmitting device or otherwise in a desired direction, a direction associated with such a directional transmission or directional reception, a set of directional resources associated with a signal transmission or signal reception (for example, an angle of arrival, a horizontal direction, or a vertical direction), or a set of parameters or resources associated with one or more aspects of a directional signal, among other examples.

In some examples, a network node 110 or a UE 120 may implement massive MIMO, which may be associated with an increased (for example, “massive”) quantity of antennas at the network node 110 or at the UE 120, such as in a network implementing mmWave technology, which enables more precise beamforming or reduced interference. In some examples, the wireless communication network 100 may implement multi-TRP (mTRP) operation (including redundant transmission or reception on multiple TRPs) or non-coherent joint transmission (NC-JT).

The network node 110 and the UE 120 may establish a communication link or beam pair, and otherwise increase reliability, throughput, signal strength, or other signal properties for MIMO communications, by performing beam management operations, such as an initial beam acquisition operation, a beam refinement operation, or a beam recovery operation. For example, an initial beam acquisition operation may involve the network node 110 transmitting signals (for example, SSBs or other signals) via respective beams (for example, of the beams 160 of the network node 110) and the UE 120 receiving and measuring the signal(s) via respective beams of multiple beams (for example, from the beams 160 of the UE 120) to identify a best beam (or beam pair) for communication between the UE 120 and the network node 110. A beam refinement operation may involve a first device (for example, the UE 120 or the network node 110) transmitting signal(s) via a subset of beams (for example, identified based on, or otherwise associated with, measurements reported as part of one or more other beam management operations). A second device (for example, the network node 110 or the UE 120) may receive the signal(s) via a single beam (for example, to identify the best beam for communication from the subset of beams). The beam(s) may be identified or defined via one or more spatial parameters, such as a transmission configuration indicator (TCI) state or a quasi co-location (QCL) parameter, among other examples.

Some aspects and techniques as described herein may be implemented, at least in part, using an artificial intelligence (AI) program (for example, referred to herein as an “AI/ML model”), such as a program that includes a machine learning (ML) model or an artificial neural network (ANN) model. The AI/ML model may be deployed at one or more devices 165 (for example, one or more network nodes 110, one or more UEs 120, one or more servers, or one or more components of a cloud computing network, among other examples). For example, in a deployment in which AI/ML functionality is performed independently at a device 165, sometimes referred to as “overlay AI/ML,” the AI/ML model (or an instance or portion of the AI/ML model) may be deployed at a UE 120 (for example, by the processing system 140), a network node 110 (for example, by the processing system 145), one or more servers, or one or more components of a cloud computing network, among other examples. Additionally, or alternatively, in a deployment where AI/ML functionality is coordinated between different devices 165, sometimes referred to as “coordinated AI/ML,” or performed at all device and network layers, sometimes referred to as “native AI/ML,” the AI/ML model (or an instance of the AI/ML model) may be deployed at multiple devices 165 (for example, a first portion of the AI/ML model may be deployed at a UE 120 and a second portion of the AI/ML model may be deployed at a network node 110). In other examples of coordinated AI/ML or native AI/ML, a first AI/ML model may be deployed at a UE 120 and a second AI/ML model may be deployed at a network node 110. The AI/ML model(s) may be configured to enhance various aspects of the wireless communication network 100 (for example, to increase privacy, reliability, or efficient use of network bandwidth, or to reduce latency, among other examples). For example, the AI/ML model(s) may be trained to identify patterns or relationships in data corresponding to the wireless communication network 100, a device, or an air interface, among other examples. The AI/ML model(s) may support operational decisions relating to one or more aspects associated with wireless communications devices, networks, or services.

Accordingly, in some examples, the AI/ML model(s) may enable AI-as-a-Service (for example, an end-to-end AI/ML service via a user plane) for use cases, such as a self-organizing network (SON), minimization of drive test (MDT), quality of experience (QoE), positioning, sensing, predictive mobility, or traffic prediction, among other examples. In some examples, AI-as-a-Service use cases may include measurement collection reporting by a UE 120, device selection criteria (for example, according to a geographical area where measurements are to be collected or UE capabilities to be used to collected measurements), or reporting configurations (for example, reporting parameters such as location, time, or sensor information, among other examples). Additionally, or alternatively, the AI/ML model(s) may enable AI/ML procedures (for example, RAN-triggered service establishment, configuration, inferencing using UE-side or network-side models, performance monitoring or management, or capability signaling, among other examples). Additionally, or alternatively, the AI/ML model(s) may enable RAN-based AI/ML services via one or more application program interfaces (APIs) or management interfaces for use cases, such as beam management, radio resource monitoring (RRM) relaxation, mobility prediction, load prediction, network energy savings, or coverage and capacity improvements, among other examples.

In the wireless communication network 100, information may be represented as a sequence of binary bits that are mapped (for example, modulated) to an analog signal waveform that is transmitted to a receiver over a wireless communication channel. In some cases, however, the wireless communication channel may introduce errors that corrupt the transmitted signal due to random noise, interference, device impairments, or other factors. At the receiver, the received signal (that may have been corrupted during transmission) is mapped back to binary bits, with the received binary information estimating the transmitted binary information. Accordingly, because errors may corrupt the signal that is estimated at the receiver, channel coding or forward error correction (FEC) techniques are often used to control errors in data transmission over unreliable or noisy communication channels or otherwise mitigate the bit errors that may occur due to noise, interference, or other factors. For example, channel coding generally includes an encoding operation performed at a transmitter (for example, a first wireless device, which may be a UE 120 or a network node 110) and a decoding operation performed at a receiver (for example, a second wireless device, which may be a UE 120 or a network node 110). Channel coding is generally accomplished by selectively introducing redundancy into the transmitted information stream, typically using an error correction code (ECC), which allows the receiver to detect errors or correct bit errors in the received data stream and thereby provide more reliable information transmission. Accordingly, channel codes are often used in scenarios where retransmissions are undesirable or high transmission reliability is needed, such as downlink or uplink control channel communications.

For example, in some cases, the wireless communication network 100 may use polar codes to implement channel coding for downlink or uplink control channel communications. More particularly, polar coding is a linear block coding technique that has provable capacity-achieving performance over binary channels with polynomial complexity in various scenarios (such as channel coding, among others). Polar coding has a built-in channel polarization structure that uses a recursive construction to split (or “polarize”) a communication channel into reliable subchannels that are very good for transmitting information and unreliable subchannels that are very bad for transmitting information. The reliable subchannels may be almost completely noiseless, with a capacity that approaches 1, and the unreliable subchannels may be almost completely noisy, with a capacity that approaches 0. During polar encoding, a polar transform is applied to assign information bits to the reliable subchannels and to assign “frozen” or “fixed” bits (for example, “0” bits) to the unreliable subchannels. For example, a polar code with a rate R=K/N may be defined according to a set of parameters {N, K, G_{N}, A}, where N is a code block length with N=2ⁿ, for n≥1, K is a code dimension, A is a data index set, A C {1, 2, . . . , N} with size |A|=K, and G_{N} is a polar transform defined by:

$${G}_{2} = [ \begin{matrix}1 & 0 \\ 1 & 1\end{matrix} ] , {G}_{N} = [ \begin{matrix}{G}_{N / 2} & 0 \\ {G}_{N / 2} & {G}_{N / 2}\end{matrix} ] = {G}_{2}^{⊗ n}$$

Given a data block d=(d₁, . . . , d_{K}), a polar code with the parameters {N, K, G_{N}, A} encodes the data block d in two steps, where the first step is to construct a transform input block u=(u₁, . . . , u_{N}) by setting:

$${u}_{A} {=}^{Δ} ( {u}_{i} : i ∈ A ) = d , {u}_{{A}^{C}} {=}^{Δ} ( {u}_{i} : i ∈ {A}^{C} ) = 0$$

and the second step is to compute the code block x by computing the polar transform of u, where x=uG_{N}. Accordingly, polar codes have an encoding/decoding complexity given by N log N, a construction complexity that is roughly O(N), and a block error probability that approaches zero roughly as 2^{-\sqrt{N}} for any fixed rate R that is less than a channel capacity (for example, there is no error floor).

In some aspects, the UE 120 may include a communication manager 150. As described in more detail elsewhere herein, the communication manager 150 may segment a payload block into multiple sub-payload blocks; independently encode each sub-payload block, of the multiple sub-payload blocks, using a spinal code encoding scheme, resulting in multiple vectors of spinal symbols; combine the multiple vectors of spinal symbols, resulting in a transmission vector; and transmit, to a receiver, a message indicating the transmission vector. Additionally, or alternatively, the communication manager 150 may receive, from a transmitter, a message indicating a transmission vector, wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols; and decode the message, resulting in information bits associated with the payload block. Additionally, or alternatively, the communication manager 150 may perform one or more other operations described herein.

In some aspects, the network node 110 may include a communication manager 155. As described in more detail elsewhere herein, the communication manager 155 may segment a payload block into multiple sub-payload blocks; independently encode each sub-payload block, of the multiple sub-payload blocks, using a spinal code encoding scheme, resulting in multiple vectors of spinal symbols; combine the multiple vectors of spinal symbols, resulting in a transmission vector; and transmit, to a receiver, a message indicating the transmission vector. Additionally, or alternatively, the communication manager 155 may receive, from a transmitter, a message indicating a transmission vector, wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols; and decode the message, resulting in information bits associated with the payload block. Additionally, or alternatively, the communication manager 155 may perform one or more other operations described herein.

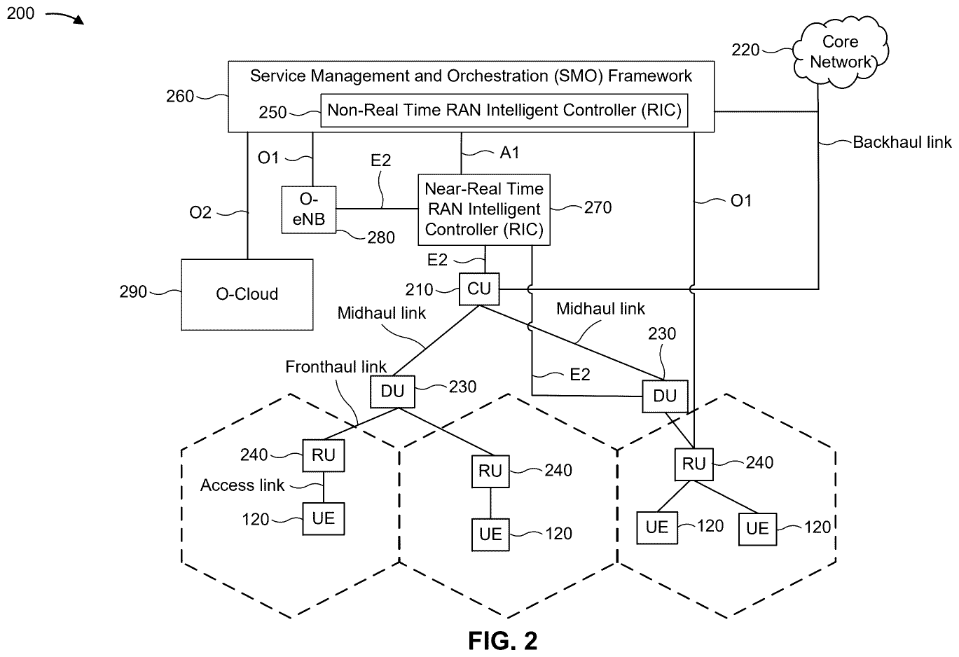

FIG. 2 is a diagram illustrating an example disaggregated network node architecture 200. One or more components of the example disaggregated network node architecture 200 may be, may include, or may be included in one or more network nodes (such one or more network nodes 110). The disaggregated network node architecture 200 may include a CU 210 that can communicate directly with a core network 220 via a backhaul link, or that can communicate indirectly with the core network 220 via one or more disaggregated control units, such as a non-real-time (Non-RT) RAN intelligent controller (RIC) 250 associated with a Service Management and Orchestration (SMO) Framework 260 or a near-real-time (Near-RT) RIC 270 (for example, via an E2 link). The CU 210 may communicate with one or more DUs 230 via respective midhaul links, such as via F1 interfaces. Each of the DUs 230 may communicate with one or more RUs 240 via respective fronthaul links. Each of the RUs 240 may communicate with one or more UEs 120 via respective RF access links. In some deployments, a UE 120 may be simultaneously served by multiple RUs 240.

Each of the components of the disaggregated network node architecture 200, including the CUS 210, the DUs 230, the RUs 240, the Near-RT RICs 270, the Non-RT RICs 250, and the SMO Framework 260, may include one or more interfaces or may be coupled with one or more interfaces for transmitting or receiving signals, such as data, control information, or reference signals via a wired or wireless transmission medium.

In some aspects, the CU 210 may be logically split into one or more CU user plane (CU-UP) units and one or more CU control plane (CU-CP) units. A CU-UP unit may communicate bidirectionally with a CU-CP unit via an interface, such as the E1 interface when implemented in an O-RAN configuration. The CU 210 may be deployed to communicate with one or more DUs 230, as necessary, for network control and signaling. Each DU 230 may correspond to a logical unit that includes one or more base station functions to control the operation of one or more RUs 240. For example, a DU 230 may host various layers, such as an RLC layer, a MAC layer, or one or more PHY layers, such as one or more high PHY layers or one or more low PHY layers. Each layer (which also may be referred to as a module) may be implemented with an interface for communicating signals with other layers (and modules) hosted by the DU 230, or for communicating signals with the control functions hosted by the CU 210. Each RU 240 may implement lower layer functionality. In some aspects, real-time and non-real-time aspects of control and user plane communication with the RU(s) 240 may be controlled by the corresponding DU 230.

The SMO Framework 260 may support RAN deployment and provisioning of non-virtualized and virtualized network elements. For non-virtualized network elements, the SMO Framework 260 may support the deployment of dedicated physical resources for RAN coverage requirements, which may be managed via an operations and maintenance interface, such as an O1 interface. For virtualized network elements, the SMO Framework 260 may interact with a cloud computing platform (such as an open cloud (O-Cloud) platform 290) to perform network element life cycle management (such as to instantiate virtualized network elements) via a cloud computing platform interface, such as an O2 interface. A virtualized network element may include, but is not limited to, a CU 210, a DU 230, an RU 240, a non-RT RIC 250, or a Near-RT RIC 270. In some aspects, the SMO Framework 260 may communicate with a hardware aspect of a 4G RAN, a 5G NR RAN, or a 6G RAN, such as an open eNB (O-eNB) 280, via an O1 interface. Additionally, or alternatively, the SMO Framework 260 may communicate directly with each of one or more RUs 240 via a respective O1 interface. In some deployments, this configuration can enable each DU 230 and the CU 210 to be implemented in a cloud-based RAN architecture, such as a vRAN architecture.

The Non-RT RIC 250 may include or may implement a logical function that enables non-real-time control and optimization of RAN elements and resources, AI/ML workflows including model training and updates, or policy-based guidance of applications or features in the Near-RT RIC 270. The Non-RT RIC 250 may be coupled to or may communicate with (such as via an A1 interface) the Near-RT RIC 270. The Near-RT RIC 270 may include or may implement a logical function that enables near-real-time control and optimization of RAN elements and resources via data collection and actions via an interface (such as via an E2 interface) connecting one or more CUs 210, one or more DUs 230, or an O-eNB 280 with the Near-RT RIC 270.

In some aspects, to generate AI/ML models to be deployed in the Near-RT RIC 270, the Non-RT RIC 250 may receive parameters or external enrichment information from external servers. Such information may be utilized by the Near-RT RIC 270 and may be received at the SMO Framework 260 or the Non-RT RIC 250 from non-network data sources or from network functions. In some examples, the Non-RT RIC 250 or the Near-RT RIC 270 may tune RAN behavior or performance. For example, the Non-RT RIC 250 may monitor long-term trends and patterns for performance and may employ AI/ML models to perform corrective actions via the SMO Framework 260 (such as reconfiguration via an O1 interface) or via creation of RAN management policies (such as A1 interface policies).

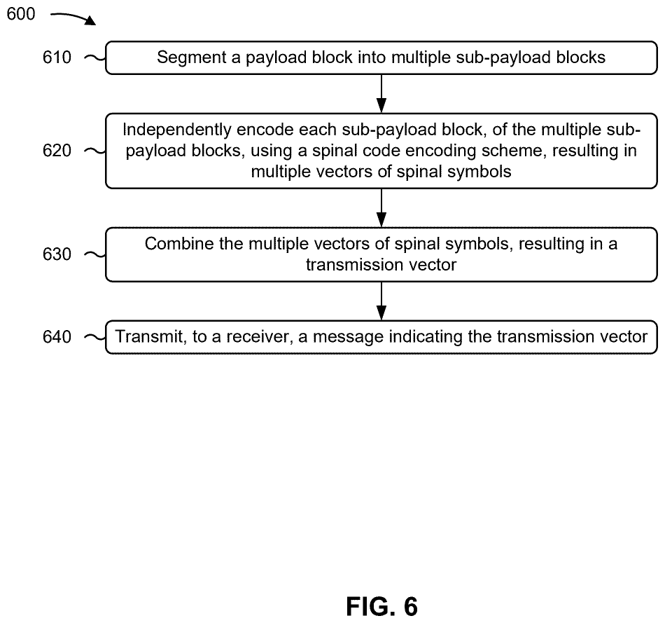

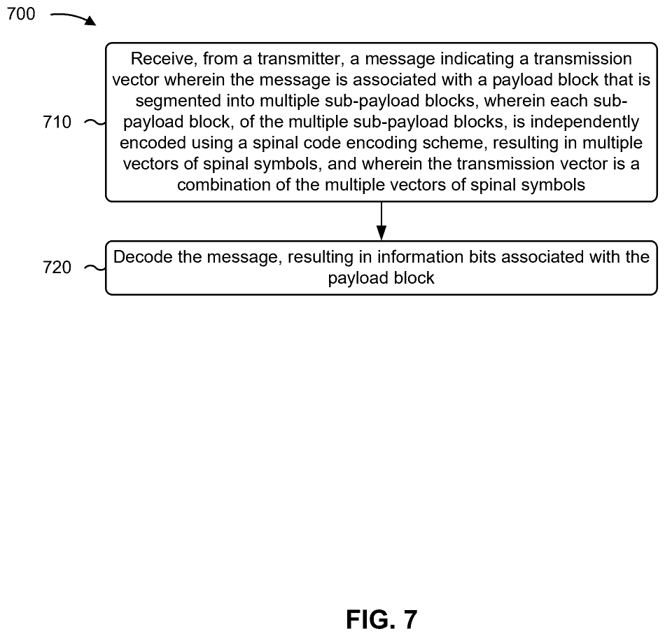

The network node 110, the processing system 145 of the network node 110, the UE 120, the processing system 140 of the UE 120, the CU 210, the DU 230, the RU 240, or any other component(s) of FIG. 1 or FIG. 2 may implement one or more techniques or perform one or more operations associated with sub-payload block spinal encoding schemes, as described in more detail elsewhere herein. For example, the processing system 145 of the network node 110, the processing system 140 of the UE 120, the CU 210, the DU 230, or the RU 240 may perform or direct operations of, for example, process 600 of FIG. 6, process 700 of FIG. 7, or other processes as described herein (alone or in conjunction with one or more other processors). In some aspects, the transmitter or receiver described herein is the network node 110, is included in the network node 110, or includes one or more components of the network node 110 shown in FIG. 1. Additionally, or alternatively, in some aspects, the transmitter or receiver described herein is the UE 120, is included in the UE 120, or includes one or more components of the UE 120 shown in FIG. 1. Memory of the network node 110 may store data and program code (or instructions) for the network node 110, the CU 210, the DU 230, or the RU 240. In some examples, the memory of the network node 110 may store data relating to a UE 120, such as RRC state information or a UE context. Memory of a UE 120 may store data and program code (or instructions) for the UE 120, such as context information. In some examples, the memory of the UE 120 or the memory of the network node 110 may include a non-transitory computer-readable medium storing a set of instructions for wireless communication. For example, the set of instructions, when executed by one or more processors (for example, of the processing system 145 or the processing system 140) of the network node 110, the UE 120, the CU 210, the DU 230, or the RU 240, may cause the one or more processors to perform process 600 of FIG. 6, process 700 of FIG. 7, or other processes as described herein. In some examples, executing instructions may include running the instructions, converting the instructions, compiling the instructions, or interpreting the instructions, among other examples.

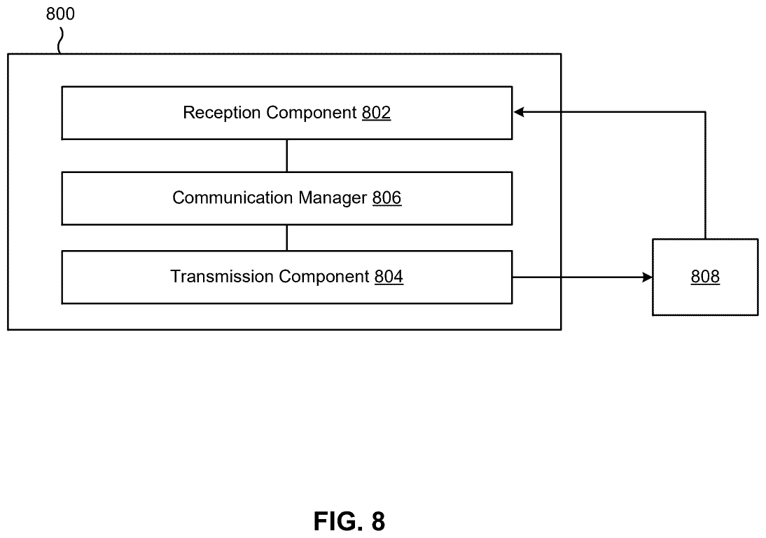

In some aspects, the UE 120 includes means for segmenting a payload block into multiple sub-payload blocks; means for independently encoding each sub-payload block, of the multiple sub-payload blocks, using a spinal code encoding scheme, resulting in multiple vectors of spinal symbols; means for combining the multiple vectors of spinal symbols, resulting in a transmission vector; or means for transmitting, to a receiver, a message indicating the transmission vector. Additionally, or alternatively, in some aspects, the UE 120 includes means for receiving, from a transmitter, a message indicating a transmission vector, wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols; or means for decoding the message, resulting in information bits associated with the payload block In some aspects, the means for the transmitter to perform operations described herein may include, for example, one or more of communication manager 150, processing system 140, a radio, one or more RF chains, one or more transceivers, one or more antennas, one or more modems, a reception component (for example, reception component 802 depicted and described in connection with FIG. 8), or a transmission component (for example, transmission component 804 depicted and described in connection with FIG. 8), among other examples.

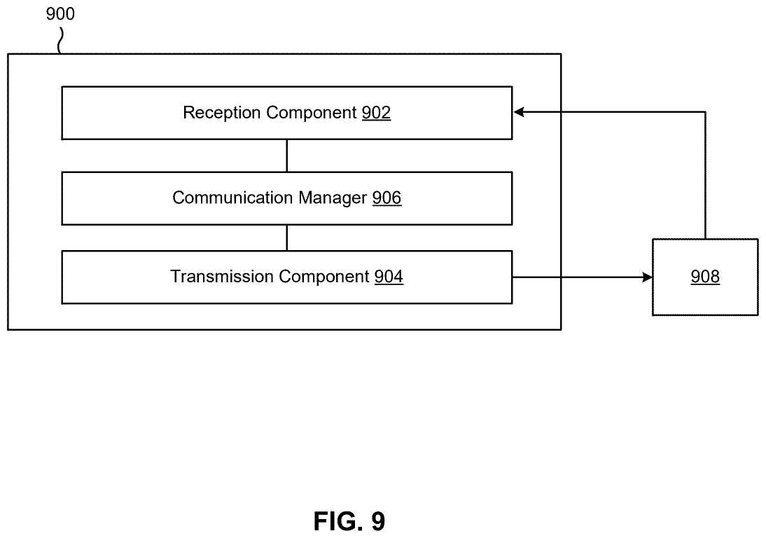

In some aspects, the network node 110 includes means for segmenting a payload block into multiple sub-payload blocks; means for independently encoding each sub-payload block, of the multiple sub-payload blocks, using a spinal code encoding scheme, resulting in multiple vectors of spinal symbols; means for combining the multiple vectors of spinal symbols, resulting in a transmission vector; or means for transmitting, to a receiver, a message indicating the transmission vector. Additionally, or alternatively, in some aspects, the network node 110 includes means for receiving, from a transmitter, a message indicating a transmission vector, wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols; or means for decoding the message, resulting in information bits associated with the payload block. In some aspects, the means for the receiver to perform operations described herein may include, for example, one or more of communication manager 155, processing system 145, a radio, one or more RF chains, one or more transceivers, one or more antennas, one or more modems, a reception component (for example, reception component 902 depicted and described in connection with FIG. 9), or a transmission component (for example, transmission component 904 depicted and described in connection with FIG. 9), among other examples.

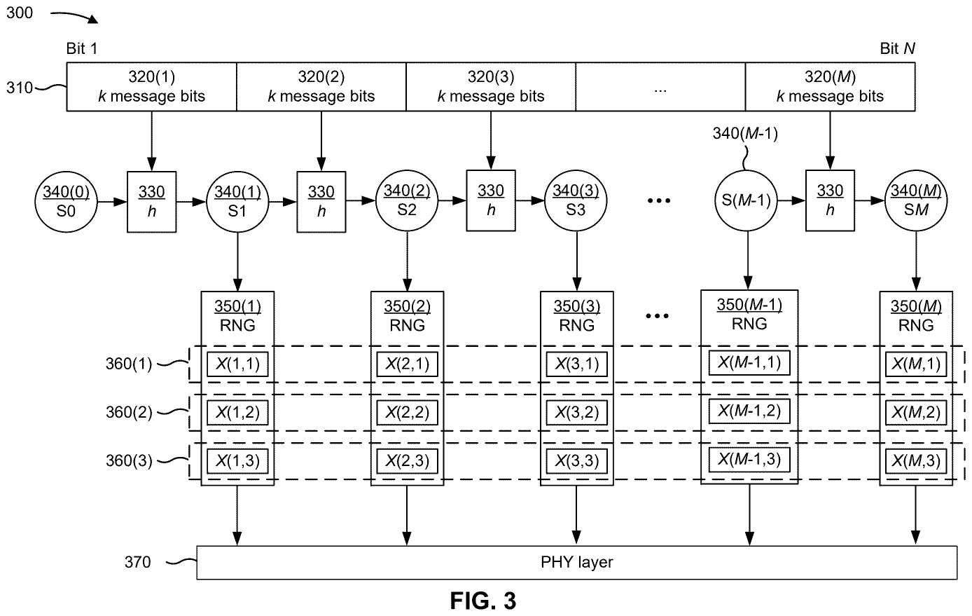

FIG. 3 is a diagram illustrating an example 300 associated with encoding of spinal codes. Other transmission schemes may involve different encoding of spinal codes.

As shown, a transmitter may break up an input message 310 into blocks (or groups, chunks, or the like) of message bits 320(1)-320(M). The message may have a total of N bits, and each of the blocks of message bits 320(1)-320(M) may have a total of k bits. Thus, the total quantity of the blocks of message bits 320(1)-320(M) may be N/k (for example, M=N/k). The transmitter may sequentially apply, to the blocks of message bits 320(1)-320(M), a hash function 330 (“h”). The hash function 330 may be designed such that a difference between two input messages in at least one bit results in a different coded sequence after the at least one bit, which may provide resilience to noise and bit errors.

The hash function 330 may also operate on v-bit states 340(0)-340(M−1), where v may be any suitable number (for example, 32). Thus, the hash function 330 may take two inputs: the blocks of message bits 320(1)-320(M) and the v-bit states 340(0)-340(M−1). The hash function 330 may output the v-bit states 340(1)-340(M) based at least in part on the blocks of message bits 320(1)-320(M) and the v-bit states 340(0)-340(M−1). In some examples, h: {0,1}^{v}×{0,1}^{k}→{0,1}^{v}. In some examples, sᵢ=h(sᵢ₋₁, m̅ᵢ), where sᵢ is an i^{th} v-bit state 340(i) and m̅ᵢ is an i^{th} block of message bits 320(i).

For example, initially, the hash function 330 may take, as input, the block of message bits 320(1) and the v-bit state 340(0). The hash function 330 and the v-bit state 340(0) may be known to the transmitter and the receiver. In some examples, the v-bit state 340(0) may be zero. The hash function 330 may output the v-bit state 340(1), take, as input, the block of message bits 320(2) and the v-bit state 340(1), and output the v-bit state 340(2). This process may continue until the hash function 330 outputs the v-bit state 340(M). In this manner, the transmitter may generate a “spine” of v bit states 340(1)-340(M) by sequentially hashing together the blocks of message bits 320(1)-320(M) from the input message 310 without adding redundancy bits.

The hash function 330 may provide the v-bit states 340(1)-340(M) as input (for example, seeds) to random number generators (RNGs) 350(1)-350(M). In some examples, the RNGs 350(1)-350(M) may be known to the transmitter and the receiver. The RNGs 350(1)-350(M) may generate sequences of random c-bit binary numbers: RNG: {0,1}^{v}×N=→{0,1}^{c}. Thus, the transmitter may randomly map the blocks of message bits 320(1)-320(M) to respective c-bit binary numbers. In some examples, a c-bit binary number may be a binary word that includes c bits. In some examples, the c-bit binary numbers may map to output IQ constellation symbols. For example, the transmitter may use a mapping function to randomly select the output IQ constellation symbols. In this manner, the transmitter may produce a sequence of coded bits and symbol for transmission. In some examples, the total quantity of the blocks of message bits 320(1)-320(M) may be equal to the total quantity of transmitted symbols.

In some examples, each of the RNGs 350(1)-350(M) may generate multiple sequences of random c-bit binary numbers. For example, in a first pass 360(1), the RNGs 350(1)-350(M) may generate first sequences of random c-bit binary numbers. The transmitter may, using the mapping function, convert the random c-bit binary numbers into first output IQ constellation symbols. The transmitter may transmit, at a PHY layer 370, one or more samples corresponding to the first output IQ constellation symbols, and if the receiver responds with a NACK, then the RNGs 350(1)-350(M) may, in a second pass 360(2), generate second sequences of random c-bit binary numbers. A sample may occupy a time window (for example, a slot) during which a transmitted signal has a given amplitude or phase corresponding to a given symbol (for example, a sample may encode a symbol). The transmitter may, using the mapping function, convert the second sequences of random c-bit binary numbers into second output IQ constellation symbols. The transmitter may transmit, at the PHY layer 370, one or more samples corresponding to the second output IQ constellation symbols, and if the receiver responds with a NACK, then the RNGs 350(1)-350(M) may, in a third pass 360(3), generate third sequences of random c-bit binary numbers. The transmitter may, using the mapping function, convert the third sequences of random c-bit binary numbers into third output IQ constellation symbols. The transmitter may transmit, at the PHY layer 370, one or more samples corresponding to the third output IQ constellation symbols. This process may continue until the transmitter receives an ACK from the receiver or a timeout occurs. As used in FIG. 3, the notation “X(Y,Z)” refers to a Z^{th} pass performed by a Y^{th} RNG. In some examples, the transmitter may transmit one symbol per v-bit state per pass; thus, if the receiver takes l passes to decode the input message 310, then the effective rate is k/l bits per channel use, where k is the maximum rate.

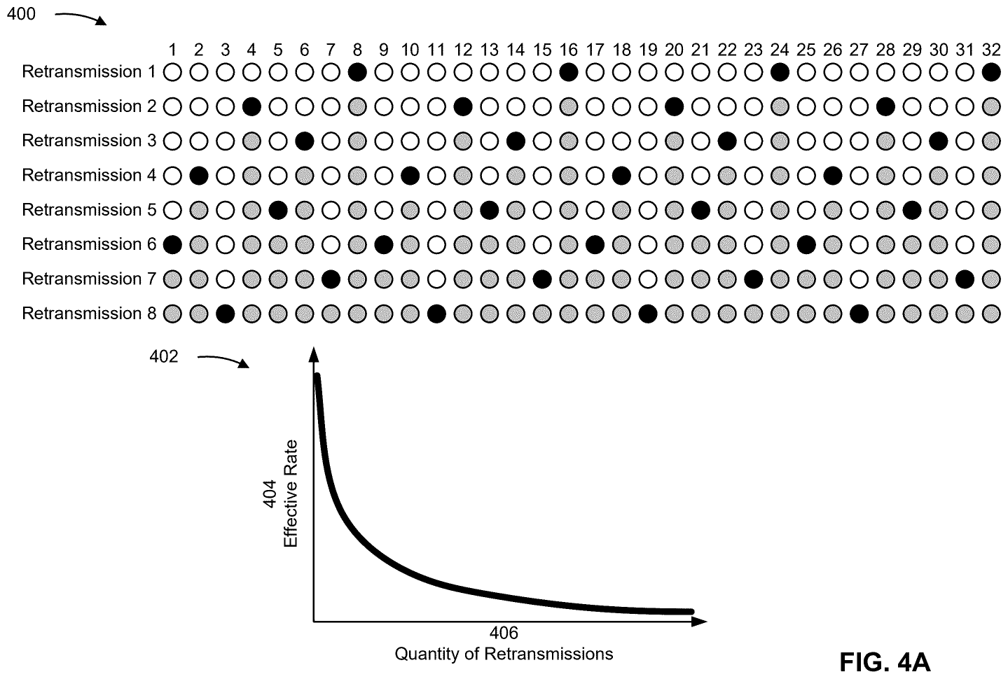

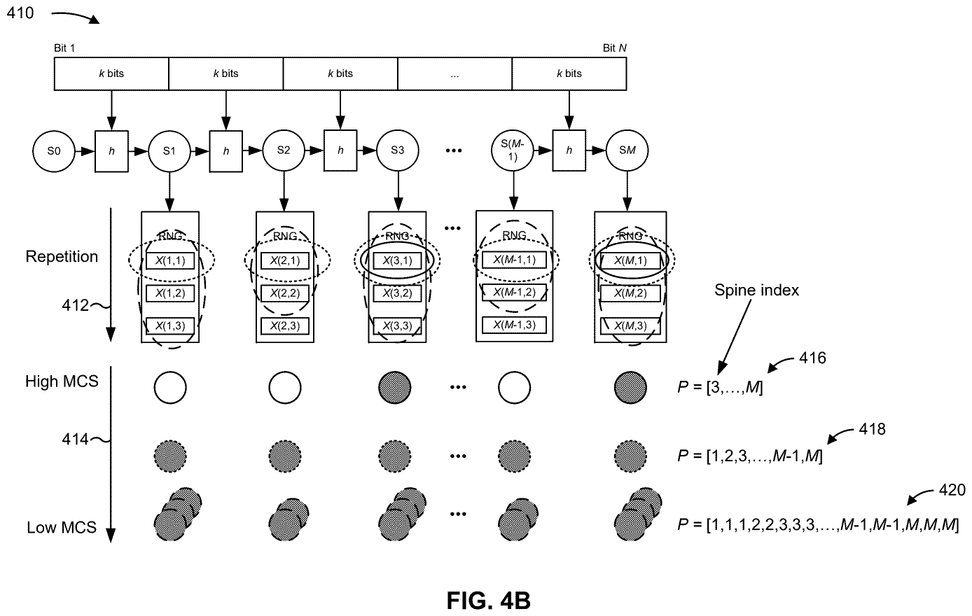

The receiver (for example, decoder) may sequentially process the received samples until the input message 310 is successfully decoded or a timeout occurs. If the timeout occurs, then the transmitter may proceed to a subsequent input message. This may be more readily understood with reference to FIGS. 4A-4B.

FIGS. 4A-4B are diagrams illustrating examples associated with a puncturing schemes for spinal codes.

As shown by FIG. 4A, and by example 400, a transmitter may transmit spinal symbols to a receiver using a quantity of retransmissions (sometimes referred to as a quantity of subpasses), indexed in FIG. 4A as retransmission 1 through retransmission 8 (but which May include more or fewer retransmissions in other examples). In each retransmission, the transmitter transmits symbols for spine values marked by black circles, while grey circles indicate symbols that have already been transmitted (for example, in a previous retransmission). In such examples, choosing a quantity of transmitted symbols per retransmission may dictate a rate granularity for the spinal code.

More particularly, in an example in which 256 message bits are to be transmitted (for example, N=256), with each block of message bits (corresponding to each circle in FIG. 4A) including eight bits (for example, k=8), the spinal code may be associated with 32 spines (for example, quantity of spines=N/k=32, as described above in connection with FIG. 3). In such an example, a quantity (for example, less than all) of the spinal symbols may be transmitted in each retransmission. More particularly, in the first retransmission, the spinal symbols associated with spines indexed 8, 16, 24, and 32 may be transmitted, shown using black circles in connection with the row corresponding to retransmission 1. In the second retransmission, the spinal symbols associated with spines indexed 4, 12, 20, and 28 may be transmitted, shown using black circles in connection with the row corresponding to retransmission 2. Moreover, because the spinal symbols associated with spines indexed 8, 16, 24, and 32 may have previously been transmitted at this point in time (for example, in retransmission 1), those spinal symbols are shown using grey circles in retransmission 2. The transmitter may continue to transmit spinal symbols in this manner until the message is successfully decoded by the receiver or until all spinal symbols have been transmitted (for example, as shown in connection with retransmission 8).

In this regard, the receiver may attempt to decode the message after each retransmission. In some examples, a receiver may decode the received spinal symbols using a bubble decoder or a bubble decoding algorithm. The bubble decoding algorithm for spinal codes involves navigating a tree of potential messages using a pruned breadth-first search approach. In this regard, each node in the tree represents a potential message, with edges corresponding to chunks of k information bits. To manage computational complexity, only a fixed quantity of B nodes are retained at each level, forming a group known as the “beam.” The decoder works with received symbols and candidate messages, scoring them based on the minimum square error (MSE) cost of the candidate message. If the quantity of nodes exceeds the prescribed maximum B, the decoder proceeds to the next spine only with those B nodes possessing lower costs. The upper bound for the count of MSE calculations in a bubble decoding process is roughly n/k·B, with the omission of calculations performed at the tree's initial stages.

Once the message is successfully decoded, the receiver may transmit an acknowledgement message to the transmitter, and the transmitter may forgo transmitting any remaining retransmissions. In that regard, in some examples the spinal code may be considered “rateless,” because a coding rate of the spinal code may not be set or may vary based on channel conditions, among other examples. For example, as shown in the plot 402, which includes an effective coding rate axis 404 and a quantity of retransmissions axis 406, an effective coding rate may decrease as a quantity of retransmissions used to transmit a message increases. Returning to the example described above, the spinal code may start a rate of 8 bits per channel use and may decrease in a manner consistent with the plot 402 as more retransmissions are used, with the total quantity of transmitted symbols per retransmission (for example, four in the above-described example 400) dictating the effective rate granularity. In some examples, using a spinal code as a rateless code may enable use of the spinal code even in the absence of utilizing CSI-RSs or similar mechanisms for determining optimal transmission schemes (for example, optimal MCSs, among other examples).

In some other examples, such as the example 410 shown in FIG. 4B, a spinal code may be associated with a fixed rate (for example, the rate of the spinal code may be determined or fixed when encoding data), in a similar manner to LDPC codes or polar codes, among other examples. For example, a spinal code encoder may limit a quantity of spinal symbols generated or a transmitter may transmit a fixed quantity of spinal symbols in a channel, thereby setting a fixed rate for the spinal code. Additionally, or alternatively, spinal codes may be used in a similar manner as LDPC codes or polar codes, however, an MCS may be used to generate an equivalent puncturing scheme for the spinal code, among other examples.

More particularly, as indicated by reference number 412, a spinal encoder may result in a quantity of repetitive symbols for each spine, in a similar manner as described above in connection with FIG. 3. Moreover, as indicated by reference number 414, an MCS may be used to generate an equivalent puncturing scheme for the spinal code, such as by using a puncturing scheme associated with relatively few spinal symbols when a high MCS is to be used, and by using a puncturing scheme associated with more spinal symbols when a low MCS is to be used. In this regard, when a spinal code is associated with a fixed rate, the puncturing scheme may specify a code rate (e.g., bits per channel use), which spines will be used to transmit a symbol, or a number of symbols to transmit for each spine. For example, as shown by reference number 416, when a high MCS is to be used, a puncturing scheme (P) may indicate that symbols associated with spine 3 and spine M are to be transmitted, and that no symbols from the other spines shown in FIG. 4B are to be transmitted (e.g., P=[3, . . . , M]). Accordingly, as shown using shaded circles in connection with reference number 416 and by using solid-line ellipses in connection with repetitive symbols indicated by reference number 412, one symbol associated with spine 3 (e.g., X(3,1)) and one symbol associated with spine M (e.g., X(M,1)) may be transmitted for this puncturing scheme or MCS. Moreover, as shown by using unshaded circles in connection with reference number 416 and by the absence of solid-line ellipses in connection with repetitive symbols indicated by reference number 412, no symbols associated with spines 1, 2, or M−1 are transmitted for this puncturing scheme or MCS.

As shown by reference number 418, when a lower MCS is to be used, a puncturing scheme may indicate that one symbol associated with each of spines 1, 2, 3, M−1, and M are to be transmitted (e.g., P=[1, 2, 3, . . . , M−1, M]). Accordingly, as shown using shaded circles in connection with reference number 418 and by using dotted-line ellipses in connection with repetitive symbols indicated by reference number 412, one symbol associated with spine 1 (e.g., X(1,1)), one symbol associated with spine 2 (e.g., X(2,1)), one symbol associated with spine 3 (e.g., X(3,1)), one symbol associated with spine M−1 (e.g., X(M−1,1)), and one symbol associated with spine M (e.g., X(M,1)) may be transmitted for this puncturing scheme or MCS.

As shown by reference number 420, when an even lower MCS is to be used, a puncturing scheme may indicate that multiple symbols (e.g., repetitive symbols) are to be transmitted for one or more spines. For example, a puncturing scheme may indicate that three symbols associated with each of spines 1, 3, and M are to be transmitted, and two symbols associated with each of spines 2 and M−1 are to be transmitted (e.g., P=[1, 1, 1, 2, 2, 3, 3, 3, . . . , M−1, M−1, M, M, M]). Accordingly, as shown using shaded circles in connection with reference number 418 and by using dashed-line ellipses in connection with repetitive symbols indicated by reference number 412, three symbol associated with spine 1 (e.g., X(1,1), X(1,2), and X(1,3)), two symbols associated with spine 2 (e.g., X(2,1) and X(2,2)), three symbol associated with spine 3 (e.g., X(3,1), X(3,2), and X(3,3)), two symbol associated with spine M−1 (e.g., X(M−1,1) and X(M−1,2)), and three symbols associated with spine M (e.g., X(M,1), X(M,2), and X(M,3)) may be transmitted for this puncturing scheme or MCS.

In some examples, using spinal codes in MIMO-based wireless communication systems may reduce losses and thus reduce communication errors, resulting in more efficient communications. For example, in a 2×2 MIMO scheme using random precoding (for example, a MIMO scheme using two transmit antennas mapped to two layers and two receive antennas mapped to the two layers), polar codes or LDPC (for example, using a bit-interleaved coded modulation (BICM) scheme) codes may result in an approximate 5 decibel (dB) gap from a Shannon limit (a theoretical maximum rate at which information can be transmitted over a communication channel with a given bandwidth and noise level, while still being able to recover the original information with negligible errors), which may include approximately 1.5 dB of shaping loss and approximately 1 dB of coding loss, as well as additional small losses such as demodulator losses, alphabet losses, or log-likelihood ratio (LLR) calculation losses, among other examples. In such an example, a potential gain of approximately 3.5 dB may be achieved using a better coded modulation scheme (for example, by using spinal codes rather than LDPC or polar codes). Similarly, for other MIMO scenarios the gain may be more significant. For example, for a 4×4 MIMO scenario using random precoding (for example, a MIMO scheme using four transmit antennas mapped to four layers and four receive antennas mapped to the four layers), a potential gain of approximately 4.5 dB may be achieved using a better coded modulation scheme (for example, by using spinal codes rather than LDPC or polar codes). In this regard, the potential gain (for example, the reduced gap from a Shannon limit) may increase with an increase in a quantity of layers.

However, the use of spinal code encoding schemes in wireless communication networks may pose certain drawbacks. For example, a spinal code encoder is a sequential encoder, because the v-bit state 340 of each spine is used a seed to the hash function 330 for the next spine. More particularly, the first v-bit state 340(1), which may be a result of inputting the first block of message bits 320(1) into the hash function 330 (e.g., inputting the first k buts into the hash function 330), may be used as a seed for the hash function 330 in the second spine. Similarly, the second v-bit state 340(2), which may be a result of inputting the second block message bits 320(2) into the hash function 330, may be used as a seed for the hash function 330 in the third spine, and so forth. In this regard, the last spine (e.g., the spine associated with the M^{th} v-bit state 340(M)), is a function of all previous spines (e.g., the spines associated with the first v-bit state 340(1) through the next-to-last v-bit state 340(M−1)). Put another way, the result of the hash function 330 in the last spine is a result of the last block of message bits 320(M) as well as all previous blocks of message bits 320.

In this regard, the spinal code encoding scheme may be relatively slow as compared to other encoding schemes, because the sequential encoder may not work in parallel on each block of message bits 320, but instead, for each block of message bits 320, the sequential encoder may need to wait for a previous v-bit state 340 to use as a seed for the hash function 330 for that block of message bits 320. Accordingly, for large CBs (e.g., packets processed by the channel coding algorithm) or similar blocks, encoding and decoding data using a spinal code encoding scheme may take a long time or may be impractical for certain applications. For example, in some wireless communication systems, such as 5G systems, a maximum CB size may be 8448 bits. Encoding the 8448 bits using a sequential decoder, such as an encoder associated with a spinal code encoding scheme, may be relatively slow, resulting in high latency and otherwise inefficient usage of network resources.

Some aspects and techniques described herein enable improved spinal code encoding schemes for wireless communications, such as spinal code encoding schemes that are faster than traditional spinal code encoding schemes when used to encode a standard code block (e.g., 8448 bits), among other examples. In some aspects, a transmitter may segment a payload block (e.g., a TB or a CB, among other examples) into multiple sub-payload blocks (e.g., sub-TBs or sub-CBs, among other examples). The transmitter may thus independently encode each sub-payload block, of the multiple sub-payload blocks, using a spinal code encoding scheme, resulting in multiple vectors of spinal symbols. The transmitter may combine the multiple vectors of spinal symbols into a transmission vector and may transmit, to a receiver, a message indicating the transmission vector.

As a result, the aspects and techniques described herein enable use of spinal code encoding schemes for wireless communications, which may exhibit increased adaptability to varying channel conditions as compared to LDPC codes or polar codes. More particularly, due to a rateless property of some spinal codes (for example, a property associated with the spinal code enabling infinite generation of encoded symbols or continuous transmission of a message until the message is decoded), the spinal code encoding schemes described herein may be better suited for unpredictable or varying channel conditions as compared to fixed-rate LDPC or polar codes, resulting in fewer communication errors in varying channels and thus less computing, power, or network resource consumption than otherwise required for correcting communication errors. Additionally or alternatively, spinal codes may be equipped to handle a variety of channels without requiring specific CSI, enabling high performance across multiple channel scenarios, further resulting in fewer communication errors and thus less computing, power, or network resource consumption than otherwise required for correcting communication errors. Moreover, by segmenting a payload block (e.g., a TB or CB) into sub-payload blocks, the aspects and techniques described herein may enable parallel encoding of large chunks of data, thereby reducing latency associated with spinal code encoding schemes and otherwise resulting in more efficient usage of network resources.

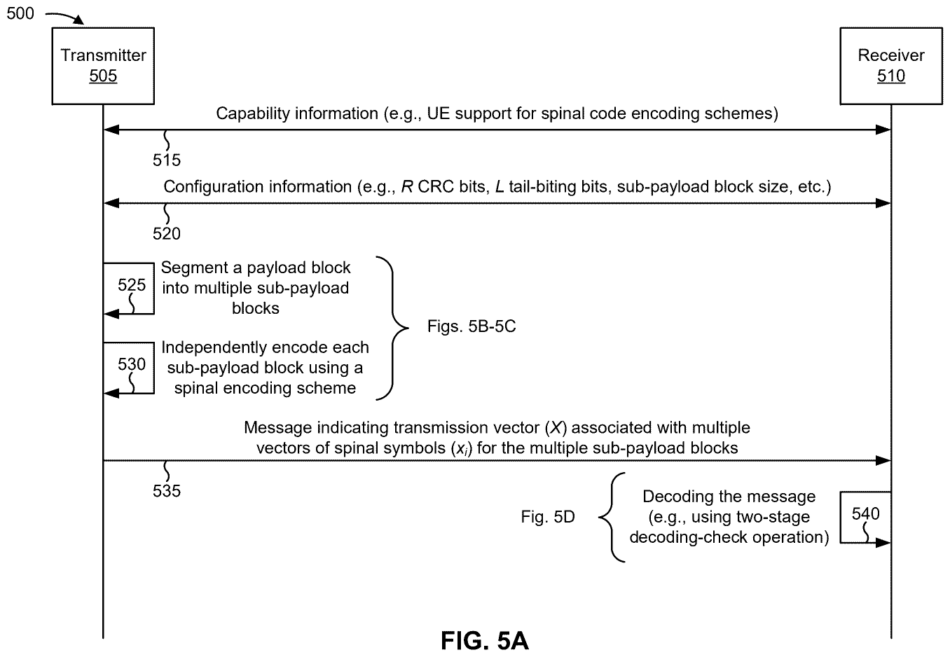

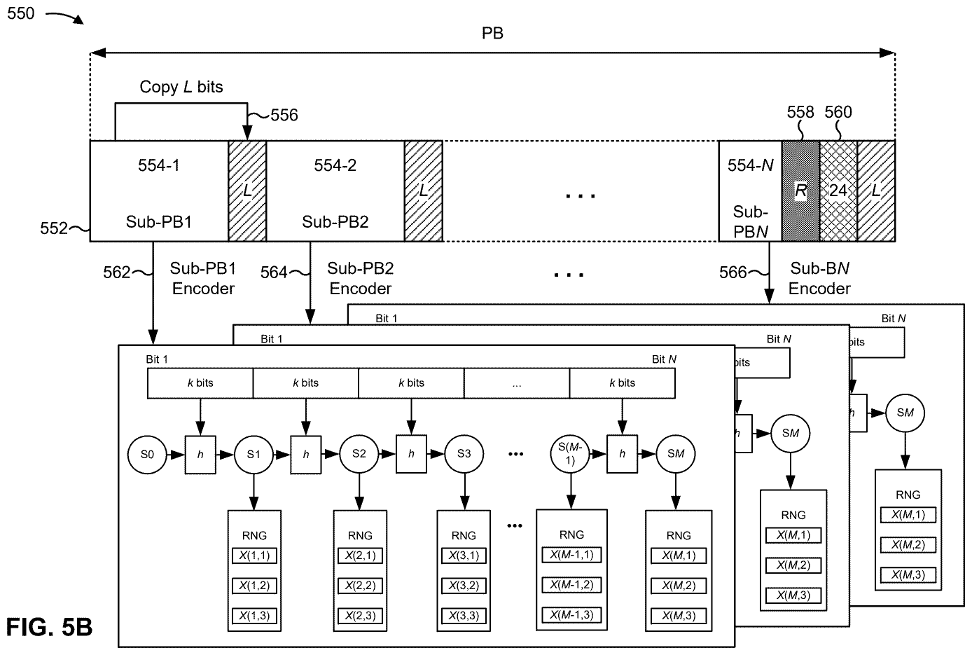

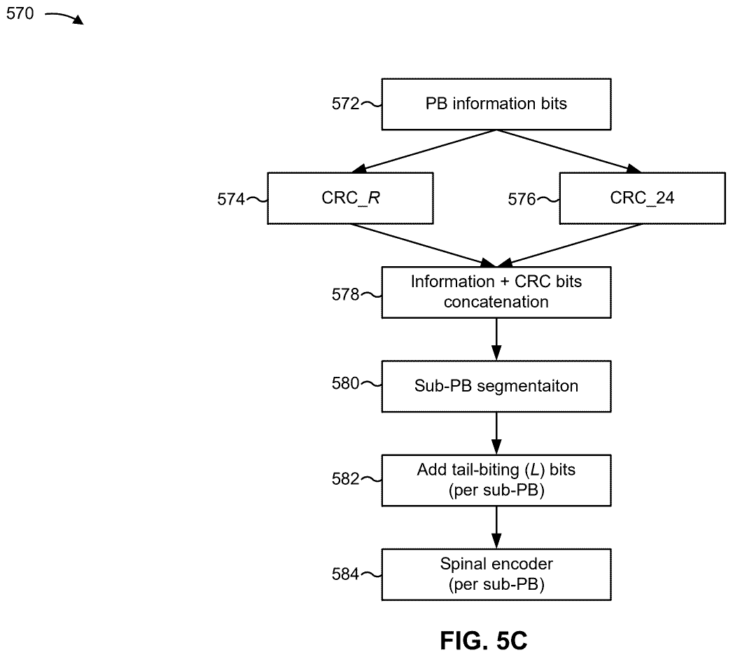

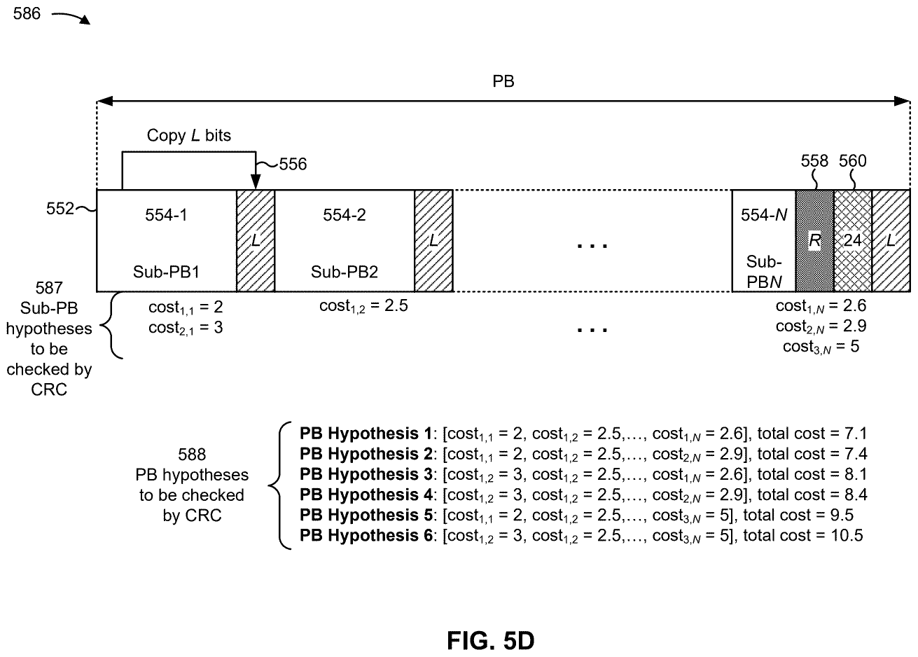

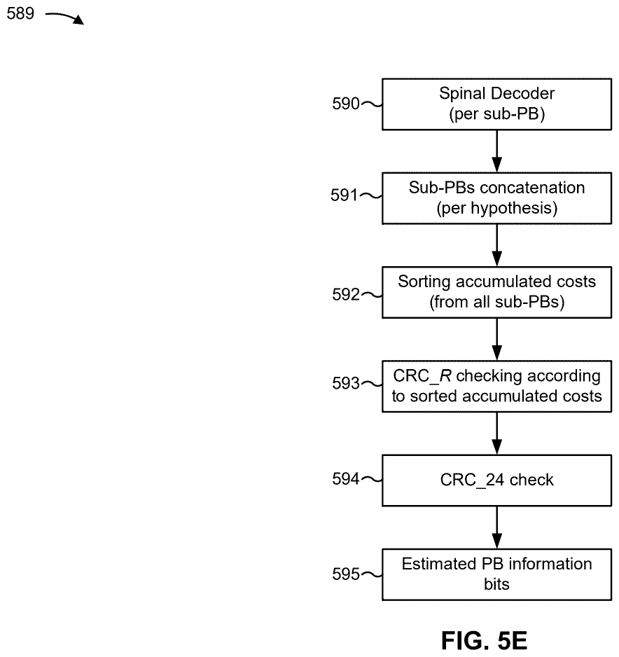

FIGS. 5A-5E are diagrams of examples associated with sub-payload block spinal code encoding schemes. As shown in FIG. 5A, and by example 500, a transmitter 505 may communicate with a receiver 510. In some aspects, the transmitter 505 may be one of a network node 110 (e.g., a base station, a CU, a DU, or an RU) or a UE 120, and the receiver 510 may be the other one of the network node 110 or the UE 120. In some other aspects, the transmitter 505 and the receiver 510 may be the same type of wireless communication device (e.g., both the transmitter 505 and the receiver 510 may be a network node 110 or both the transmitter 505 and the receiver 510 may be a UE 120, among other examples). In some aspects, the transmitter 505 and the receiver 510 may be part of a wireless network (e.g., the wireless communication network 100). The transmitter 505 and the receiver 510 may have established a wireless connection prior to operations shown in FIG. 5A. In some aspects, the transmitter 505 and the receiver 510 may be capable of communicating using spinal code encoding schemes. For example, as described in more detail herein, the transmitter 505 may be capable of encoding communications using a spinal code encoding scheme, and the receiver 510 may be capable of decoding messages that are encoded using a spinal code encoding scheme.

In some aspects, as shown by reference number 515, the transmitter 505 and the receiver 510 may communicate capability information. For example, in aspects in which the transmitter 505 is a UE 120 and the receiver 510 is a network node 110, the transmitter 505 (e.g., the UE 120) may transmit, and the receiver 510 (e.g., the network node 110) may receive, the capability information. In aspects in which the receiver 510 is a UE 120 and the transmitter 505 is a network node 110, the receiver 510 (e.g., the UE 120) may transmit, and the transmitter 505 (e.g., the network node 110) may receive, the capability information. The capability information may be included in a capability report. The capability information may be transmitted via an uplink communication, a sidelink communication, a unicast communication, a broadcast communication, a UE assistance information (UAI) communication, a UCI communication, a sidelink control information (SCI) communication, a MAC-CE communication, an RRC communication, a PUCCH, a PUSCH, a physical sidelink control channel (PSCCH), or a physical sidelink shared channel (PSSCH), among other examples. The capability information may indicate one or more parameters associated with respective capabilities of a UE 120. The one or more parameters may be indicated via respective information elements (IEs) included in a capability report.

The capability information may indicate whether the transmitter 505 or the receiver 510 supports a feature or one or more parameters related to the feature. For example, the capability information may indicate a capability or parameter for supporting spinal code encoding schemes. As another example, the capability information may indicate a capability or parameter for supporting sub-payload block (sub-PB) (e.g., sub-TB or sub-CB) spinal code encoding schemes. One or more operations described herein may be based on capability information. For example, the transmitter 505 or the receiver 510 may perform a communication in accordance with the capability information, or may receive configuration information that is in accordance with the capability information. In some aspects, the capability information may indicate support for segmenting a payload block into multiple sub-payload blocks and independently encoding each sub-payload block using a spinal code encoding scheme (such as in aspects in which the transmitter 505 corresponds to a UE 120). In some other aspects, the capability information may indicate support for decoding a message associated with a payload block that is segmented into multiple sub-payload blocks, with each sub-payload block being independently encoded using a spinal code encoding scheme (such as in aspects in which the receiver 510 corresponds to a UE 120).

As shown by reference number 520, the transmitter 505 and the receiver 510 may communicate configuration information. For example, in aspects in which the transmitter 505 is a UE 120 and the receiver 510 is a network node 110, the receiver 510 (e.g., the network node 110) may transmit, and the transmitter 505 (e.g., the UE 120) may receive, the configuration information. In aspects in which the receiver 510 is a UE 120 and the transmitter 505 is a network node 110, the transmitter 505 (e.g., the network node 110) may transmit, and the receiver 510 (e.g., the UE 120) may receive, the configuration information. In some aspects, the transmitter 505 or the receiver 510 may receive the configuration information via one or more of system information signaling (e.g., a master information block (MIB) or a system information block (SIB), among other examples), RRC signaling, MAC signaling (e.g., one or more MAC-CEs), or physical layer signaling (e.g., DCI), among other examples.

In some aspects, the configuration information may indicate one or more candidate configurations or communication parameters. In some aspects, the one or more candidate configurations or communication parameters may be selected, activated, or deactivated by a subsequent indication. For example, the subsequent indication may select a candidate configuration or communication parameter from the one or more candidate configurations or communication parameters. In some aspects, the subsequent indication may include a dynamic indication, such as one or more MAC-CEs or one or more DCI messages, among other examples.

In some aspects, the configuration information may include an indication of a selection of one or more configuration parameters (e.g., a selection of the one or more configuration parameters already known to the transmitter 505 or the receiver 510 or previously indicated by a network node or other network device), or explicit configuration information for the transmitter 505 or the receiver 510 to use to configure the transmitter 505 or the receiver 510, among other examples.

In some examples, the configuration information may not be expressly signaled to the transmitter 505 or the receiver 510. For example, in some aspects, the configuration information may at least partially be defined by a wireless communication standard, such as the 3GPP. In such examples, a network node may not explicitly indicate such configuration information to the transmitter 505 or the receiver 510. For example, the transmitter 505 or the receiver 510 may optionally obtain at least a portion of the configuration information from a configuration stored by the transmitter 505 or the receiver 510 (e.g., an original equipment manufacturer (OEM) configuration). In some aspects, the configuration information may include a parameter or index that is indicative of information defined, or otherwise fixed, by a wireless communication standard, such as the 3GPP (e.g., rather than explicitly indicating the information).

In some aspects, the configuration information may indicate that the transmitter 505 or the receiver 510 is to communicate using a spinal code encoding scheme. Additionally, or alternatively, the configuration information may indicate that the transmitter 505 or the receiver 510 is to communicate using a sub-payload block spinal code encoding scheme, such as a spinal code encoding scheme in which a payload block (e.g., a TB or CB, among other examples) is segmented into multiple sub-payload blocks, and in which each sub-payload block is independently encoded using a spinal code encoding scheme, as described in more detail herein.

In some aspects, the configuration information may indicate one or more parameters associated with the sub-payload block spinal code encoding scheme. For example, the configuration information may indicate a quantity of CRC bits (e.g., R CRC bits) associated with a first-stage-decoding-check operation (which is described in more detail below). Additionally, or alternatively, the configuration information may indicate a quantity of bits (e.g., L bits) associated with a portion of information bits to be copied and concatenated to an end of a sub-payload block (e.g., as part of a tail-biting operation, which is described in more detail below). In some aspects, the values of R and L may be optimized or set according to a particular application or channel conditions. For example, based at least in part on channel conditions (e.g., SINR, interference, fading conditions, or the like), link quality (e.g., bit error rate (BER), block error rate (BLER), HARQ ACK/NACK metrics, or the like), channel feedback (e.g., CSI or the like), device capabilities (e.g., transmitter or receiver processing power, antenna configurations, hardware limitations, or the like), network policies or constraints (e.g., quality of service (QoS) requirements, power constraints, resource allocation considerations, or the like), UE mobility, or similar considerations, the transmitter 505 or the receiver 510 may select a value of R or L and signal the value of R or L to the other one of the transmitter 505 or the receiver 510.

The transmitter 505 or the receiver 510 may configure itself based at least in part on the configuration information. In some aspects, the transmitter 505 or the receiver 510 may be configured to perform one or more operations described herein based at least in part on the configuration information.

As indicated by reference number 525, the transmitter 505 may segment a payload block (e.g., a TB or a CB, among other examples) into multiple sub-payload blocks (e.g., multiple sub-TBs or multiple sub-CBs, among other examples). For example, in aspects in which the payload block is associated with an 8448-bit CB, the transmitter 505 may segment the CB into multiple (e.g., N) sub-CBs, each associated with a subset of the 8448 bits (e.g., each associated with 1/N×8448 bits), among other examples.

In some aspects, the payload block may be associated with information bits and CRC bits, and thus segmenting the payload block into the sub-payload blocks may include segmenting a combination of the information bits and the CRC bits into the sub-payload blocks. For example, in some aspects, the transmitter 505 may determine, using information bits of the payload block, CRC bits for the payload block, and thus the transmitter 505 may segment a concatenation of the information bits and the CRC bits into the multiple sub-payload blocks, which is described in more detail below in connection with FIG. 5B.

Additionally, or alternatively, in some aspects the payload block may be associated with multiple sets of CRC bits, such as a first set of CRC bits associated with a first-stage-decoding-check operation and a second set of CRC bits associated with a second-stage-decoding-check operation, which are described in more detail below in connection with FIGS. 5B-5E. In such aspects, the transmitter 505 may determine the first set of CRC bits and the second set of CRC bits, and then segment a concatenation of the information bits, the first set of CRC bits, and the second set of CRC bits into the sub-payload blocks. In some aspects, the configuration information described above in connection with reference number 520 may indicate the quantity of bits to be used for the first-stage-decoding-check operation and or the second-stage-decoding-check operation. For example, the configuration information may indicate a quantity (e.g., R) of the first set of CRC bits, and a quantity of the second set of CRC bits may be predefined (e.g., specified by a relevant wireless communication standard, such as 3GPP), preconfigured, hard-coded, or otherwise indicated to the transmitter 505 or receiver 510. For example, in some aspects, the first set of CRC bits may be associated with R bits (and thus are sometimes collectively referred to herein as “CRC_R”), and the second set of CRC bits may be associated with 24 bits (and thus are sometimes collectively referred to herein as “CRC_24”). Aspects associated with a CRC_R operation and a CRC_24 operation are described in more detail below in connection with FIGS. 5B-5E.

In some aspects, each sub-payload block may include redundant bits (sometimes referred to herein as “tail-biting bits”) used to enable improved decoding operations (which is described in more detail below in connection with reference number 540 and FIGS. 5D-5E). For example, a first portion of information bits of each sub-payload block (e.g., the first L bits of each sub-payload block, with, in some aspects, a value of L being indicated to the transmitter 505 or receiver 510 via the configuration information described above in connection with reference number 520) may be copied and included in the sub-payload block as redundant bits. In such aspects, the transmitter 505 may, for each sub-payload block, copy a portion of information bits (e.g., L bits) from a beginning portion of that sub-payload block, resulting in a copied portion of information bits, and concatenate the copied portion of information bits (e.g., the L bits) to an end portion of that sub-payload block, which is described in more detail below in connection with FIGS. 5B-5C.

As indicated by reference number 530, the transmitter 505 may independently encode each sub-payload block using a spinal code encoding scheme (e.g., the spinal code encoding scheme described above in connection with FIGS. 3-4), resulting in multiple vectors of spinal symbols. In this way, because the payload block is segmented into the multiple sub-payload blocks, and because each sub-payload block is independently encoded using the spinal code encoding scheme, the multiple sub-payload blocks may be encoded in parallel by the transmitter 505 (and thus decoded in parallel by the receiver 510, once received), thereby reducing latency as compared to examples in which an entire payload block is associated with a single spinal code encoding scheme (e.g., due to the sequential encoding nature of the spinal code encoding schemes, as described above). Moreover, as indicated by reference number 535, the transmitter 505 may combine the multiple vectors of spinal symbols (with each vector corresponding to a respective sub-payload block) into a transmission vector and transmit the transmission vector to the receiver 510. Put another way, the transmitter 505 may concatenate the multiple vectors of spinal symbols, with each vector of spinal symbols sometimes referred to herein as xi (where i is the index of the sub-payload block), into a transmission vector (sometimes referred to herein as X), and the transmitter 505 may transmit, to the receiver 510, a message indicating the transmission vector, X (e.g., the concatenation of the spinal symbols resulting from the independent encoding operations described above in connection with reference number 530).

As indicated by reference number 540, the receiver 510 may decode the received message (e.g., X), resulting in information bits associated with the payload block. In this regard, because the spinal code encoding scheme was performed on the sub-payload blocks (e.g., a subset of 8448 bits, in aspects in which the payload block is a CB associated with 8448 bits), the decoding process may use smaller trees as compared to a decoding process in which the spinal code encoding scheme was performed on a payload block (e.g., an 8448-bit CB, among other examples). Put another way, in some aspects, the decoding process at the receiver 510 utilizes smaller trees, which may lower the likelihood of exceeding the maximum allowed number of hypotheses (e.g., B) and otherwise simplify the decoding process. For example, rather than decoding the message using a tree size proportional to

$${( {2}^{α} )}^{\frac{n}{k}}$$

(where α is a constant that represents the average increment factor of the tree from spine to spine), the decoder may decode the message using n_{CB} trees (where n_{CB} corresponds to the quantity of sub-payload blocks in which the payload block was segmented into) that have sizes proportional to

$${( {2}^{α} )}^{\frac{n / {n}_{CB}}{k}} .$$

In this regard, a decoding complexity may be proportional to

$${n}_{CB} \cdot {( {2}^{α} )}^{\frac{n / {n}_{CB}}{k}} < {( {2}^{α} )}^{\frac{n}{k}} .$$

In some aspects, the receiver 510 may decode the message using soft decoding process for each sub-payload block. For example, the receiver may, for each sub-payload block (e.g., each xi), collect all hypotheses that pass a tail-biting check (e.g., that pass a check associated with the copied L bits for that sub-payload block). Put another way, the receiver 510 may determine, for each sub-payload block, one or more sub-payload-block hypotheses and a subset of the one or more sub-payload-block hypotheses that pass a check associated with the copied portion of information bits (e.g., the L bits). For example, the receiver 510 may compare the last L bits of each hypothesis with the first L bits of that hypothesis, and may eliminate any hypothesis for which the last L bits differ from the first L bits (because, in aspects involving the tail-biting bits, the encoder copied the first L bits and concatenated the copied Z bits to the end of the sub-payload block). In this regard, the tail-biting check may drop out most hypotheses for each sub-payload block.

Once the receiver has collected all hypotheses that pass the tail-biting check (e.g., in aspects involving the L bits), the receiver 510 may sort the remaining hypotheses according to cost (e.g., from a lowest MSE cost to a highest MSE cost, among other examples). The receiver 510 may then perform a CRC check on concatenations of sub-payload-block hypotheses (with a concatenation of sub-payload-block hypotheses sometimes referred to herein a payload-block hypothesis), beginning with a concatenation of the sub-payload block hypotheses having a lowest cost, and then proceeding with other iterations of payload-block hypotheses, if necessary (e.g., if the concatenation of the sub-payload block hypotheses having the lowest cost does not pass the CRC check). For example, in a first iteration, the receiver may perform a CRC check on a concatenation of a sub-payload-block hypothesis for a first sub-payload block that has a lowest cost for that sub-payload block, a sub-payload-block hypothesis for a second sub-payload block that has a lowest cost for that sub-payload block, and so forth through a sub-payload-block hypothesis for an N^{th} sub-payload block that has a lowest cost for that sub-payload block. If that payload-block hypothesis does not pass the CRC check, in a second iteration, the receiver may perform a CRC check on a different payload-block hypothesis having a next-lowest cost, and so forth.

Moreover, as described above in connection with reference number 525, in some aspects the payload block may be associated with a first set of CRC bits associated with a first-stage-decoding-check operation (e.g., CRC_R bits) and a second set of CRC bits associated with a second-stage-decoding-check operation (e.g., CRC_24 bits). In such aspects, the receiver 510 may perform a two-step CRC check, in which the receiver 510 determines a payload-block hypothesis that passes a CRC check using the R bits, and then performs a CRC check on that payload-block hypothesis using the 24 bits. Put another way, in some aspects, the receiver 510 may decode the message by determining, for each sub-payload block, one or more sub-payload-block hypotheses, determining multiple payload-block hypotheses, each payload-load hypothesis including a concatenation of selected sub-payload-block hypotheses, performing the first-stage-decoding-check operation on the multiple payload-block hypotheses using the first set of CRC bits (e.g., the R bits), and performing the second-stage-decoding-check operation, using the second set of CRC bits (e.g., 24 bits), on a payload-block hypothesis that passes the first-stage-decoding-check operation. Aspects regarding the decoding operation are described in more detail below in connection with FIGS. 5D-5E.

FIG. 5B shows an example 550 associated with segmenting a payload block (PB) 552 (e.g., a TB, a CB, or a similar payload block) into multiple sub-PBs 554 (shown as a first sub-PB 554-1 through an N^{th} sub-PB 554-N). As indicated by reference number 556, in aspects involving the tail-biting aspects described above, the first L bits of each sub-PB 554 may be copied and concatenated at an end of that sub-PB 554. Moreover, in some aspects, the PB 552 may be associated with CRC bits, such as CRC_R bits (as shown by reference number 558) and CRC_24 bits (as shown by reference number 560). In that regard, certain sub-PBs 554 may encode only information bits, while other sub-PBs 554 may encode information bits or CRC bits. For example, the N^{th} sub-PB 554-N in FIG. 5B may encode information bits, the CRC_R bits, and the CRC_24 bits, with the first L information bits, the CRC_R bits, or the CRC_24 bits copied and concatenated at the end of the N^{th} sub-PB 554-N.

In such aspects, each sub-PB 554 may be independently (and, in some aspects, parallelly) encoded using a spinal code encoding scheme, such as the spinal code encoding scheme described above in connection with FIG. 3, among other examples. More particularly, the first sub-PB 554-1 may be encoded using a first spinal code encoder, as indicated by reference number 562, the second sub-PB 554-2 may be encoded using a second spinal code encoder, as indicated by reference number 564, and so forth, through the N^{th} sub-PB 554-N being encoded using an N^{th} spinal code encoder, as indicated by reference number 566.

FIG. 5C shows a flowchart 570 associated with the transmitter 505 encoding the PB 552 shown in FIG. 5B. As indicated by reference number 572, the transmitter 505 (more particularly, an encoding component of the transmitter, such as a spinal code encoding component of the transmitter 505) may receive the PB information bits that are to be encoded for a message. As indicated by reference number 574, the transmitter 505 may determine R CRC bits for the PB information bits (e.g., a CRC_R operation may be performed for all PB information bits). R may be equal to zero or more than zero, and R may, in some aspects, be signaled via the configuration information described in connection with reference number 520. Moreover, as indicated by reference number 576, the transmitter 505 may determine 24 CRC bits for the PB information bits (e.g., CRC_24 may be performed for all PB information bits).

As indicated by reference number 578, the transmitter 505 may concatenate the CRC bits (e.g., the CRC_R bits and the CRC_24 bits) to the PB information bits. As indicated by reference number 580, the transmitter may segment the concatenated PB information bits and CRC bits into sub-PBs (e.g., sub-PBs 554). Moreover, in aspects involving the tail-biting check described above in connection with FIG. 5A, the transmitter may add the tail-biting bits (e.g., the L bits) to each sub-PB 554, as indicated by reference number 582, such as by copying the first L bits of each sub-PB 554 and concatenating the copied L bits at the end of that sub-PB 554. In some aspects, L may be equal to zero or more than zero, and L may, in some aspects, be signaled via the configuration information described in connection with reference number 520. As indicated by reference number 584, the transmitter may independently encode each sub-PB 554, such as by utilizing a per sub-PB 554 spinal encoder (as described above in connection with FIG. 5B and reference numbers 562, 564, and 566), resulting in the encoded message to be transmitted to the receiver 510.

FIG. 5D shows an example 586 associated with decoding the PB 552 at the receiver 510(more particularly, a decoding component of the receiver 510, such as a spinal code decoding component or similar decoding component). As described above in connection with FIG. 5A, the receiver 510 may collect all hypotheses that pass a tail-biting check, which may cause most hypotheses to drop out. For example, as indicated by reference number 587, following the tail-biting check, the first sub-PB 554-1 may be associated with two remaining hypotheses, the second sub-PB 554-2 may be associated with one remaining hypothesis, and the N^{th} sub-PB 554-N may be associated with three remaining hypotheses. As further indicated by reference number 587, the receiver sort the remaining hypotheses by cost. For example, a cost of a first hypothesis associated with the first sub-PB 554-1 (denoted as cost_{1,1}) may be 2 in this example, and a cost of a second hypothesis associated with the first sub-PB 554-1 (denoted as cost_{2,1}) may be 3 in this example. Moreover, a cost of the only remaining hypothesis associated with the second sub-PB 554-2 (denoted as cost_{1,2}) may be 2.5 in this example. Additionally, a cost of a first hypothesis associated with the N^{th} sub-PB 554-N (denoted as cost₁,N) may be 2.6 in this example, a cost of a second hypothesis associated with the N^{th} sub-PB 554-N (denoted as cost_{2,N}) may be 2.9 in this example, and a cost of a third hypothesis associated with the N^{th} sub-PB 554-N (denoted as cost_{3,N}) may be 5 in this example.

As indicated by reference number 588, the receiver may perform a joint CRC procedure (e.g., using the R bits) on PB hypotheses (e.g., hypotheses associated with concatenated sub-PB hypotheses), beginning with a PB hypothesis associated with a lowest accumulated cost. For example, ignoring for ease of description the sub-PB hypotheses and respective costs associate with a third sub-PB through a next-to-last sub-PB, the sub-PB hypotheses that passed the tail-biting check result in six different combinations of sub-PB hypotheses (e.g., six different PB hypotheses), shown in connection with reference number 588 as being sorted from a PB hypothesis associated with a lowest total cost through a PB hypothesis associated with a highest total cost. More particularly, a first PB hypothesis may be associated with a first hypothesis for the first sub-PB 554-1, a first hypothesis for the second sub-PB 554-2, and a first hypothesis for the N^{th} sub-PB 554-N, associated with a total cost of 7.1 (e.g., cost_{1,1}=2, cost_{1,2}=2.5, . . . , and cost_{1,N}=2.6, for a total cost=7.1). A second PB hypothesis may be associated with the first hypothesis for the first sub-PB 554-1, the first hypothesis for the second sub-PB 554-2, and a second hypothesis for the N^{th} sub-PB 554-N, for a total cost of 7.4 (e.g., cost_{1,1}=2, cost_{1,2}=2.5, . . . , and cost_{2,N}=2.9, for a total cost=7.4), and so forth. In some aspects, the receiver 510 may perform a CRC_R check on up to 2^{R} PB hypotheses. For any PB hypotheses that passes the CRC_R check, the receiver 510 may perform a second-stage CRC check, such as by using the CRC_24 bits. If a PB hypothesis passes the CRC_R check and the CRC_24 check, the receiver 510 may treat that PB hypothesis as the estimated PB information bits (e.g., the decoded message).

FIG. 5E shows a flowchart 589 associated with the receiver 510 decoding the PB 552 shown in FIG. 5D. As indicated by reference number 590, the receiver 510 may perform per sub-PB spinal code decoding, such as by independently decoding each sub-PB 554, resulting in one or more sub-PB hypotheses for each sub-PB 554. In aspects involving the tail-biting features described above (e.g., in aspects in which the sub-PBs 554 include the L redundant bits), the receiver 510 may eliminate any sub-PB hypotheses that do not pass the tail-biting check, as described above.

As indicated by reference number 591, the receiver 510 may perform sub-PBs concatenation, such as by concatenating each combination of the sub-PB hypotheses to form multiple PB hypotheses, as described above in connection with reference number 588. As indicated by reference number 592, the receiver 510 may sort the PB hypotheses according to accumulated costs (e.g., from lowest total cost to highest total cost), in a similar manner as described above in connection with reference number 588.

As indicated by reference number 593, the receiver 510 may perform a first-stage CRC check (e.g., a CRC_R check) on the PB hypotheses, starting with the PB hypothesis having the lowest total cost. For example, the receiver 510 may perform a CRC_R check on a first PB hypothesis associated with a lowest total cost, then may perform a CRC_R check on a second PB hypothesis associated with a next-lowest total cost, and so forth. As indicated by reference number 594, once a certain PB hypothesis passes the first-stage check (e.g., the CRC_R check), the receiver 510 may perform a second-stage CRC check (e.g., a CRC_24 check). Moreover, as indicated by reference number 595, if a PB hypothesis passes both the first-stage and second-stage CRC checks, the receiver 510 may use that PB hypothesis as the estimated PB information bits (e.g., the decoded message).

Based at least in part on the transmitter 505 and the receiver 510 independently encoding and decoding sub-payload blocks using a sub-payload block spinal code encoding scheme, the transmitter 505 and the receiver 510 may conserve computing, power, network, or communication resources that may have otherwise been consumed traditional channel encoding and decoding algorithms. For example, based at least in part on the transmitter 505 and the receiver 510 independently encoding and decoding sub-payload blocks using a sub-payload block spinal code encoding scheme, the transmitter 505 and the receiver 510 may communicate with a reduced error rate, which may conserve computing, power, network, or communication resources that may have otherwise been consumed to detect or correct communication errors.

As indicated above, FIGS. 5A-5E are provided as examples. Other examples may differ from what is described with respect to FIGS. 5A-5E.

FIG. 6 is a diagram illustrating an example process 600 performed, for example, at a transmitter or an apparatus of a transmitter. Example process 600 is an example where the apparatus or the transmitter (e.g., transmitter 505) performs operations associated with sub-payload block spinal encoding schemes.

As shown in FIG. 6, in some aspects, process 600 may include segmenting a payload block into multiple sub-payload blocks (block 610). For example, the transmitter (e.g., using communication manager 806, depicted in FIG. 8, or communication manager 906, depicted in FIG. 9) may segment a payload block into multiple sub-payload blocks, as described above.

As further shown in FIG. 6, in some aspects, process 600 may include independently encoding each sub-payload block, of the multiple sub-payload blocks, using a spinal code encoding scheme, resulting in multiple vectors of spinal symbols (block 620). For example, the transmitter (e.g., using communication manager 806, depicted in FIG. 8, or communication manager 906, depicted in FIG. 9) may independently encode each sub-payload block, of the multiple sub-payload blocks, using a spinal code encoding scheme, resulting in multiple vectors of spinal symbols, as described above.

As further shown in FIG. 6, in some aspects, process 600 may include combining the multiple vectors of spinal symbols, resulting in a transmission vector (block 630). For example, the transmitter (e.g., using communication manager 806, depicted in FIG. 8, or communication manager 906, depicted in FIG. 9) may combine the multiple vectors of spinal symbols, resulting in a transmission vector, as described above.

As further shown in FIG. 6, in some aspects, process 600 may include transmitting, to a receiver, a message indicating the transmission vector (block 640). For example, the transmitter (e.g., using transmission component 804 or communication manager 806, depicted in FIG. 8, or transmission component 904 or communication manager 906, depicted in FIG. 9) may transmit, to a receiver, a message indicating the transmission vector, as described above.

Process 600 may include additional aspects, such as any single aspect or any combination of aspects described below or in connection with one or more other processes described elsewhere herein.

In a first aspect, process 600 includes determining, using information bits of the payload block, CRC bits for the payload block, wherein segmenting the payload block into the multiple sub-payload blocks includes segmenting a concatenation of the information bits and the CRC bits into the multiple sub-payload blocks.

In a second aspect, alone or in combination with the first aspect, the CRC bits include a first set of CRC bits associated with a first-stage-decoding-check operation and a second set of CRC bits associated with a second-stage-decoding-check operation.

In a third aspect, alone or in combination with one or more of the first and second aspects, process 600 includes communicating, with the receiver, configuration information indicating a quantity of bits associated with the first set of CRC bits.

In a fourth aspect, alone or in combination with one or more of the first through third aspects, segmenting the payload block into the multiple sub-payload blocks includes, for each sub-payload block, of the multiple sub-payload blocks copying a portion of information bits from a beginning portion of that sub-payload block, resulting in a copied portion of information bits, and concatenating the copied portion of information bits to an end portion of that sub-payload block.

In a fifth aspect, alone or in combination with one or more of the first through fourth aspects, process 600 includes communicating, with the receiver, configuration information indicating a quantity of bits associated with the portion of information bits.

Although FIG. 6 shows example blocks of process 600, in some aspects, process 600 may include additional blocks, fewer blocks, different blocks, or differently arranged blocks than those depicted in FIG. 6. Additionally, or alternatively, two or more of the blocks of process 600 may be performed in parallel.

FIG. 7 is a diagram illustrating an example process 700 performed, for example, at a receiver or an apparatus of a receiver. Example process 700 is an example where the apparatus or the receiver (e.g., receiver 510) performs operations associated with sub-payload block spinal encoding schemes.

As shown in FIG. 7, in some aspects, process 700 may include receiving, from a transmitter, a message indicating a transmission vector, wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols (block 710). For example, the receiver (e.g., using reception component 802 or communication manager 806, depicted in FIG. 8, or reception component 902 or communication manager 906, depicted in FIG. 9) may receive, from a transmitter, a message indicating a transmission vector, wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols, as described above.

As further shown in FIG. 7, in some aspects, process 700 may include decoding the message, resulting in information bits associated with the payload block (block 720). For example, the receiver (e.g., using communication manager 806, depicted in FIG. 8, or communication manager 906, depicted in FIG. 9) may decode the message, resulting in information bits associated with the payload block, as described above.

Process 700 may include additional aspects, such as any single aspect or any combination of aspects described below or in connection with one or more other processes described elsewhere herein.

In a first aspect, the message is associated with the information bits and CRC bits associated with the information bits, and a concatenation of the information bits and the CRC bits is segmented into the multiple sub-payload blocks.

In a second aspect, alone or in combination with the first aspect, the CRC bits include a first set of CRC bits associated with a first-stage-decoding-check operation and a second set of CRC bits associated with a second-stage-decoding-check operation.

In a third aspect, alone or in combination with one or more of the first and second aspects, process 700 includes communicating, with the transmitter, configuration information indicating a quantity of bits associated with the first set of CRC bits.

In a fourth aspect, alone or in combination with one or more of the first through third aspects, decoding the message includes determining, for each sub-payload block, of the multiple sub-payload blocks, one or more sub-payload-block hypotheses, determining multiple payload-block hypotheses, each payload-load hypothesis, of the multiple payload-block hypotheses, including a concatenation of selected sub-payload-block hypotheses, performing the first-stage-decoding-check operation on the multiple payload-block hypotheses using the first set of CRC bits, and performing the second-stage-decoding-check operation on a selected payload-block hypothesis, of the multiple payload-block hypotheses, using the second set of CRC bits, wherein the selected payload-block hypothesis is selected based at least in part on performing the first-stage-decoding-check operation.

In a fifth aspect, alone or in combination with one or more of the first through fourth aspects, the payload block is segmented into the multiple sub-payload blocks such that, for each sub-payload block, of the multiple sub-payload blocks a portion of information bits from a beginning portion of that sub-payload block is copied, resulting in a copied portion of information bits, and the copied portion of information bits is concatenated to an end portion of that sub-payload block.

In a sixth aspect, alone or in combination with one or more of the first through fifth aspects, process 700 includes communicating, with the transmitter, configuration information indicating a quantity of bits associated with the portion of information bits.

In a seventh aspect, alone or in combination with one or more of the first through sixth aspects, decoding the message includes determining, for each sub-payload block, of the multiple sub-payload blocks one or more sub-payload-block hypotheses, and a subset of the one or more sub-payload-block hypotheses that pass a check associated with the copied portion of information bits, and decoding the message based at least in part on using the subset of the one or more sub-payload-block hypotheses associated with each sub-payload block.

Although FIG. 7 shows example blocks of process 700, in some aspects, process 700 may include additional blocks, fewer blocks, different blocks, or differently arranged blocks than those depicted in FIG. 7. Additionally, or alternatively, two or more of the blocks of process 700 may be performed in parallel.

FIG. 8 is a diagram of an example apparatus 800 for wireless communication. The apparatus 800 may be a UE, or a UE may include the apparatus 800. In some aspects, the apparatus 800 includes a reception component 802, a transmission component 804, or a communication manager 806, which may be in communication with one another (for example, via one or more buses or one or more other components). In some aspects, the communication manager 806 is the communication manager 150 described in connection with FIG. 1. As shown, the apparatus 800 may communicate with another apparatus 808, such as a UE or a network node (such as a CU, a DU, an RU, or a base station), using the reception component 802 and the transmission component 804. The communication manager 806 may be included in, or implemented via, a processing system (for example, the processing system 140 described in connection with FIG. 1) of the UE.

In some aspects, the apparatus 800 may be configured to perform one or more operations described herein in connection with FIGS. 5A-5E. Additionally, or alternatively, the apparatus 800 may be configured to perform one or more processes described herein, such as process 600 of FIG. 6, process 700 of FIG. 7, or a combination thereof. In some aspects, the apparatus 800 or one or more components shown in FIG. 8 may include one or more components of the UE described in connection with FIG. 1. Additionally, or alternatively, one or more components shown in FIG. 8 may be implemented within one or more components described in connection with FIG. 1. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 802 may receive communications, such as reference signals, control information, data communications, or a combination thereof, from the apparatus 808. The reception component 802 may provide received communications to one or more other components of the apparatus 800. In some aspects, the reception component 802 may perform signal processing on the received communications, and may provide the processed signals to the one or more other components of the apparatus 800. In some aspects, the reception component 802 may include one or more components of the UE described above in connection with FIG. 1, such as a radio, one or more RF chains, one or more transceivers, or one or more modems, each of which may in turn be coupled with one or more antennas of the UE.

The transmission component 804 may transmit communications, such as reference signals, control information, data communications, or a combination thereof, to the apparatus 808. In some aspects, one or more other components of the apparatus 800 may generate communications and may provide the generated communications to the transmission component 804 for transmission to the apparatus 808. In some aspects, the transmission component 804 may perform signal processing on the generated communications, and may transmit the processed signals to the apparatus 808. In some aspects, the transmission component 804 may include one or more components of the UE described above in connection with FIG. 1, such as a radio, one or more RF chains, one or more transceivers, or one or more modems, each of which may in turn be coupled with one or more antennas of the UE described in connection with FIG. 1. In some aspects, the transmission component 804 may be co-located with the reception component 802.

The communication manager 806 may support operations of the reception component 802 or the transmission component 804. For example, the communication manager 806 may receive information associated with configuring reception of communications by the reception component 802 or transmission of communications by the transmission component 804. Additionally, or alternatively, the communication manager 806 may generate or provide control information to the reception component 802 or the transmission component 804 to control reception or transmission of communications.

The communication manager 806 may segment a payload block into multiple sub-payload blocks. The communication manager 806 may independently encode each sub-payload block, of the multiple sub-payload blocks, using a spinal code encoding scheme, resulting in multiple vectors of spinal symbols. The communication manager 806 may combine the multiple vectors of spinal symbols, resulting in a transmission vector. The transmission component 804 may transmit, to a receiver, a message indicating the transmission vector.

The communication manager 806 may determine, using information bits of the payload block, CRC bits for the payload block wherein segmenting the payload block into the multiple sub-payload blocks includes segmenting a concatenation of the information bits and the CRC bits into the multiple sub-payload blocks.

The communication manager 806 may communicate, with the receiver, configuration information indicating a quantity of bits associated with the first set of CRC bits.

The communication manager 806 may communicate, with the receiver, configuration information indicating a quantity of bits associated with the portion of information bits.

The reception component 802 may receive, from a transmitter, a message indicating a transmission vector wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols. The communication manager 806 may decode the message, resulting in information bits associated with the payload block.

The communication manager 806 may communicate, with the transmitter, configuration information indicating a quantity of bits associated with the first set of CRC bits.

The communication manager 806 may communicate, with the transmitter, configuration information indicating a quantity of bits associated with the portion of information bits.

The number and arrangement of components shown in FIG. 8 are provided as an example. In practice, there may be additional components, fewer components, different components, or differently arranged components than those shown in FIG. 8. Furthermore, two or more components shown in FIG. 8 may be implemented within a single component, or a single component shown in FIG. 8 may be implemented as multiple, distributed components. Additionally, or alternatively, a set of (one or more) components shown in FIG. 8 may perform one or more functions described as being performed by another set of components shown in FIG. 8.

FIG. 9 is a diagram of an example apparatus 900 for wireless communication. The apparatus 900 may be a network node, or a network node may include the apparatus 900. In some aspects, the apparatus 900 includes a reception component 902, a transmission component 904, or a communication manager 906, which may be in communication with one another (for example, via one or more buses or one or more other components). In some aspects, the communication manager 906 is the communication manager 155 described in connection with FIG. 1. As shown, the apparatus 900 may communicate with another apparatus 908, such as a UE or a network node (such as a CU, a DU, an RU, or a base station), using the reception component 902 and the transmission component 904. The communication manager 906 may be included in, or implemented via, a processing system (for example, the processing system 145 described in connection with FIG. 1) of the network node.

In some aspects, the apparatus 900 may be configured to perform one or more operations described herein in connection with FIGS. 5A-5E. Additionally, or alternatively, the apparatus 900 may be configured to perform one or more processes described herein, such as process 600 of FIG. 6, process 700 of FIG. 7, or a combination thereof. In some aspects, the apparatus 900 or one or more components shown in FIG. 9 may include one or more components of the network node described in connection with FIG. 1. Additionally, or alternatively, one or more components shown in FIG. 9 may be implemented within one or more components described in connection with FIG. 1. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 902 may receive communications, such as reference signals, control information, data communications, or a combination thereof, from the apparatus 908. The reception component 902 may provide received communications to one or more other components of the apparatus 900. In some aspects, the reception component 902 may perform signal processing on the received communications, and may provide the processed signals to the one or more other components of the apparatus 900. In some aspects, the reception component 902 may include one or more components of the network node described above in connection with FIG. 1, such as a radio, one or more RF chains, one or more transceivers, or one or more modems, each of which may in turn be coupled with one or more antennas of the network node. In some aspects, the reception component 902 or the transmission component 904 may include or may be included in a network interface. The network interface may be configured to obtain or output signals for the apparatus 900 via one or more communications links, such as a backhaul link, a midhaul link, or a fronthaul link.

The transmission component 904 may transmit communications, such as reference signals, control information, data communications, or a combination thereof, to the apparatus 908. In some aspects, one or more other components of the apparatus 900 may generate communications and may provide the generated communications to the transmission component 904 for transmission to the apparatus 908. In some aspects, the transmission component 904 may perform signal processing on the generated communications, and may transmit the processed signals to the apparatus 908. In some aspects, the transmission component 904 may include one or more components of the network node described above in connection with FIG. 1, such as a radio, one or more RF chains, one or more transceivers, or one or more modems, each of which may in turn be coupled with one or more antennas of the network node described in connection with FIG. 1. In some aspects, the transmission component 904 may be co-located with the reception component 902.

The communication manager 906 may support operations of the reception component 902 or the transmission component 904. For example, the communication manager 906 may receive information associated with configuring reception of communications by the reception component 902 or transmission of communications by the transmission component 904. Additionally, or alternatively, the communication manager 906 may generate or provide control information to the reception component 902 or the transmission component 904 to control reception or transmission of communications.

The communication manager 906 may segment a payload block into multiple sub-payload blocks. The communication manager 906 may independently encode each sub-payload block, of the multiple sub-payload blocks, using a spinal code encoding scheme, resulting in multiple vectors of spinal symbols. The communication manager 906 may combine the multiple vectors of spinal symbols, resulting in a transmission vector. The transmission component 904 may transmit, to a receiver, a message indicating the transmission vector.

The communication manager 906 may determine, using information bits of the payload block, CRC bits for the payload block wherein segmenting the payload block into the multiple sub-payload blocks includes segmenting a concatenation of the information bits and the CRC bits into the multiple sub-payload blocks.

The communication manager 906 may communicate, with the receiver, configuration information indicating a quantity of bits associated with the first set of CRC bits.

The communication manager 906 may communicate, with the receiver, configuration information indicating a quantity of bits associated with the portion of information bits.

The reception component 902 may receive, from a transmitter, a message indicating a transmission vector wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols. The communication manager 906 may decode the message, resulting in information bits associated with the payload block.

The communication manager 906 may communicate, with the transmitter, configuration information indicating a quantity of bits associated with the first set of CRC bits.

The communication manager 906 may communicate, with the transmitter, configuration information indicating a quantity of bits associated with the portion of information bits.

The number and arrangement of components shown in FIG. 9 are provided as an example. In practice, there may be additional components, fewer components, different components, or differently arranged components than those shown in FIG. 9. Furthermore, two or more components shown in FIG. 9 may be implemented within a single component, or a single component shown in FIG. 9 may be implemented as multiple, distributed components. Additionally, or alternatively, a set of (one or more) components shown in FIG. 9 may perform one or more functions described as being performed by another set of components shown in FIG. 9.

The following provides an overview of some Aspects of the present disclosure:

Aspect 1: A method of wireless communication performed by a transmitter, comprising: segmenting a payload block into multiple sub-payload blocks; independently encoding each sub-payload block, of the multiple sub-payload blocks, using a spinal code encoding scheme, resulting in multiple vectors of spinal symbols; combining the multiple vectors of spinal symbols, resulting in a transmission vector; and transmitting, to a receiver, a message indicating the transmission vector.

Aspect 2: The method of Aspect 1, further comprising: determining, using information bits of the payload block, cyclic redundancy check (CRC) bits for the payload block, wherein segmenting the payload block into the multiple sub-payload blocks includes segmenting a concatenation of the information bits and the CRC bits into the multiple sub-payload blocks.

Aspect 3: The method of Aspect 2, wherein the CRC bits include a first set of CRC bits associated with a first-stage-decoding-check operation and a second set of CRC bits associated with a second-stage-decoding-check operation.

Aspect 4: The method of Aspect 3, further comprising communicating, with the receiver, configuration information indicating a quantity of bits associated with the first set of CRC bits.

Aspect 5: The method of any of Aspects 1-4, wherein segmenting the payload block into the multiple sub-payload blocks includes, for each sub-payload block, of the multiple sub-payload blocks: copying a portion of information bits from a beginning portion of that sub-payload block, resulting in a copied portion of information bits; and concatenating the copied portion of information bits to an end portion of that sub-payload block.

Aspect 6: The method of Aspect 5, further comprising communicating, with the receiver, configuration information indicating a quantity of bits associated with the portion of information bits.

Aspect 7: A method of wireless communication performed by a receiver, comprising: receiving, from a transmitter, a message indicating a transmission vector, wherein the message is associated with a payload block that is segmented into multiple sub-payload blocks, wherein each sub-payload block, of the multiple sub-payload blocks, is independently encoded using a spinal code encoding scheme, resulting in multiple vectors of spinal symbols, and wherein the transmission vector is a combination of the multiple vectors of spinal symbols; and decoding the message, resulting in information bits associated with the payload block.

Aspect 8: The method of Aspect 7, wherein the message is associated with the information bits and cyclic redundancy check (CRC) bits associated with the information bits, and wherein a concatenation of the information bits and the CRC bits is segmented into the multiple sub-payload blocks.

Aspect 9: The method of Aspect 8, wherein the CRC bits include a first set of CRC bits associated with a first-stage-decoding-check operation and a second set of CRC bits associated with a second-stage-decoding-check operation.

Aspect 10: The method of Aspect 9, further comprising communicating, with the transmitter, configuration information indicating a quantity of bits associated with the first set of CRC bits.

Aspect 11: The method of Aspect 9, wherein decoding the message includes: determining, for each sub-payload block, of the multiple sub-payload blocks, one or more sub-payload-block hypotheses; determining multiple payload-block hypotheses, each payload-load hypothesis, of the multiple payload-block hypotheses, including a concatenation of selected sub-payload-block hypotheses; performing the first-stage-decoding-check operation on the multiple payload-block hypotheses using the first set of CRC bits; and performing the second-stage-decoding-check operation on a selected payload-block hypothesis, of the multiple payload-block hypotheses, using the second set of CRC bits, wherein the selected payload-block hypothesis is selected based at least in part on performing the first-stage-decoding-check operation.

Aspect 12: The method of any of Aspects 7-11, wherein the payload block is segmented into the multiple sub-payload blocks such that, for each sub-payload block, of the multiple sub-payload blocks: a portion of information bits from a beginning portion of that sub-payload block is copied, resulting in a copied portion of information bits; and the copied portion of information bits is concatenated to an end portion of that sub-payload block.

Aspect 13: The method of Aspect 12, further comprising communicating, with the transmitter, configuration information indicating a quantity of bits associated with the portion of information bits.

Aspect 14: The method of Aspect 12, wherein decoding the message includes: determining, for each sub-payload block, of the multiple sub-payload blocks: one or more sub-payload-block hypotheses, and a subset of the one or more sub-payload-block hypotheses that pass a check associated with the copied portion of information bits; and decoding the message based at least in part on using the subset of the one or more sub-payload-block hypotheses associated with each sub-payload block.

Aspect 15: An apparatus for wireless communication at a device, the apparatus comprising one or more processors; one or more memories coupled with the one or more processors; and instructions stored in the one or more memories and executable by the one or more processors to cause the apparatus to perform the method of one or more of Aspects 1-14.

Aspect 16: An apparatus for wireless communication at a device, the apparatus comprising one or more memories and one or more processors coupled to the one or more memories, the one or more processors configured to cause the device to perform the method of one or more of Aspects 1-14.

Aspect 17: An apparatus for wireless communication, the apparatus comprising at least one means for performing the method of one or more of Aspects 1-14.

Aspect 18: A non-transitory computer-readable medium storing code for wireless communication, the code comprising instructions executable by one or more processors to perform the method of one or more of Aspects 1-14.

Aspect 19: A non-transitory computer-readable medium storing a set of instructions for wireless communication, the set of instructions comprising one or more instructions that, when executed by one or more processors of a device, cause the device to perform the method of one or more of Aspects 1-14.

Aspect 20: A device for wireless communication, the device comprising a processing system that includes one or more processors and one or more memories coupled with the one or more processors, the processing system configured to cause the device to perform the method of one or more of Aspects 1-14.

Aspect 21: An apparatus for wireless communication at a device, the apparatus comprising one or more memories and one or more processors coupled to the one or more memories, the one or more processors individually or collectively configured to cause the device to perform the method of one or more of Aspects 1-14.

Aspect 22: A device comprising a processing system that includes one or more processors and one or more code-storing memories coupled with the one or more processors, the processing system configured to cause the device to perform the method of one or more of Aspects 1-14.

Aspect 23: A device comprising a processing system that includes processor circuitry and code-storing memory circuitry, the processing system configured to cause the device to perform the method of one or more of Aspects 1-14.

It will be apparent that systems or methods described herein may be implemented in different forms of hardware or a combination of hardware and software. A component being configured to perform a function means that the component has a capability to perform the function, and does not require the function to be actually performed by the component, unless noted otherwise.

As used herein, the term “determine” or “determining” can encompass one or more of a wide variety of actions. For example, “determining” can include one or more of calculating, computing, processing, deriving, detecting, estimating, investigating, looking up, inferring, ascertaining, measuring, resolving, selecting, choosing, obtaining, identifying, interpreting, demodulating, decoding, reading, establishing, forming or generating, among other examples. In some such examples, determining can involve a processor performing some type of calculating, computing, deriving, estimating, inferring, ascertaining, resolving, predicting or other processing to obtain one or more numerical values, sets, elements or other information or results. In some other such examples, determining can involve a processor identifying, looking up, investigating or otherwise obtaining some type of value, set, element or other information or result from a table, a data structure, a database or other memory device or location. In some other such examples, determining can involve a processor identifying, interpreting, demodulating, decoding, detecting, reading or otherwise obtaining some type of value, set, element or other information or result signaled in, for example, a received wireless packet. In some other such examples, determining can involve a processor selecting or choosing one or more values, sets, elements or other information or results from a larger set of values, sets elements or other information or results. In some other such examples, determining can involve a processor performing a measurement, such as on a received signal.

As used herein, the articles “a” and “an” are intended to refer to one or more items and may be used interchangeably with “one or more” or “at least one.” As used herein, a phrase referring to “at least one of” or “one or more of” a list of items refers to any combination of those items, including single members. As an example, “at least one of: a, b, or c” is intended to cover: a, b, c, a-b, a-c, b-c, and a-b-c. Additionally, as used herein, a phrase referring to “a” or “an” element refers to one or more of such elements acting individually or collectively to perform the recited function(s). Additionally, as used herein, a “set” can refer to one or more items, and a “subset” can refer to a whole set or less than the whole set, but not an empty set. “Set,” “group,” and similar terms are intended to include one or more items and may be used interchangeably with “one or more.” Furthermore, as used herein, the term “or” is intended to be interpreted in the inclusive sense (such as when referring to a series) and may be used interchangeably with “and/or,” unless otherwise explicitly indicated (for example, if used in conjunction with “either” or “only one of”). For example, “A or B” may include A only, B only, or a combination of A and B. Also, as used herein, the terms “has,” “have,” “having,” “comprise,” “comprising,” “include” and “including,” and derivatives thereof or similar terms are intended to be open-ended terms that do not limit an element that they modify (for example, an element “having” A also may have B).

As used herein, the phrase “associated with” is intended to be interpreted in the inclusive sense, unless otherwise explicitly indicated. For example, the phrase “associated with” is not to be construed as a reference to a closed set of conditions, factors, criteria, elements, components, or actions, among other examples. Specifically, unless a phrase refers to “associated with only ‘a,’” or the equivalent in context, whatever it is that is “associated with ‘a,’” may be associated with “a” alone or associated with a combination of “a” and one or more other conditions, factors, criteria, elements, components, or actions, among other examples. In various examples, the phrase “associated with” may be interpreted to mean “in association with,” “in accordance with,” “based on,” “based at least in part on,” “as a function of,” “in response to,” “responsive to,” or “using” as appropriate in the relevant context unless otherwise explicitly indicated. Furthermore, what follows the phrase “associated with,” “in association with,” “in accordance with,” “based on,” “based at least in part on,” “as a function of,” “in response to,” “responsive to,” or “using” is not necessarily the focal point or primary factor associated with the limitation preceding the phrase.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples.

Even though particular combinations of features are recited in the claims or disclosed in the specification, these combinations are not intended to limit the scope of all aspects described herein. Many of these features may be combined in ways not specifically recited in the claims or disclosed in the specification. The disclosure of various aspects includes each dependent claim in combination with every other claim in the claim set.

What is claimed is:

1. A transmitter, comprising:
a processing system that includes one or more processors and one or more code-storing memories coupled with the one or more processors, the processing system configured to cause the transmitter to:
segment a payload block into multiple sub-payload blocks;
independently encode each sub-payload block, of the multiple sub-payload blocks, using a spinal code encoding scheme, resulting in multiple vectors of spinal symbols;
combine the multiple vectors of spinal symbols, resulting in a transmission vector; and
transmit, to a receiver, a message indicating the transmission vector.

2. The transmitter of claim 1, wherein the processing system is configured to cause the transmitter to:
determine, using information bits of the payload block, cyclic redundancy check (CRC) bits for the payload block,
wherein the processing system, to cause the transmitter to segment the payload block into the multiple sub-payload blocks, is configured to cause the transmitter to segment a concatenation of the information bits and the CRC bits into the multiple sub-payload blocks.

3. The transmitter of claim 2, wherein the CRC bits include a first set of CRC bits associated with a first-stage-decoding-check operation and a second set of CRC bits associated with a second-stage-decoding-check operation.

4. The transmitter of claim 3, wherein the processing system is configured to cause the transmitter to communicate, with the receiver, configuration information indicating a quantity of bits associated with the first set of CRC bits.

5. The transmitter of claim 1, wherein the processing system, to cause the transmitter to segment the payload block into the multiple sub-payload blocks, is configured to cause the transmitter to for each sub-payload block, of the multiple sub-payload blocks:
copy a portion of information bits from a beginning portion of that sub-payload block, resulting in a copied portion of information bits; and
concatenate the copied portion of information bits to an end portion of that sub-payload block.

6. The transmitter of claim 5, wherein the processing system is configured to cause the transmitter to communicate, with the receiver, configuration information indicating a quantity of bits associated with the portion of information bits.

7. A receiver, comprising:
a processing system that includes one or more processors and one or more code-storing memories coupled with the one or more processors, the processing system configured to cause the receiver to:
receive, from a transmitter, a message indicating a transmission vector,
wherein the message is associated with a payload block that is segmented into multiple sub-payload blocks,
wherein each sub-payload block, of the multiple sub-payload blocks, is independently encoded using a spinal code encoding scheme, resulting in multiple vectors of spinal symbols, and
wherein the transmission vector is a combination of the multiple vectors of spinal symbols; and
decode the message, resulting in information bits associated with the payload block.

8. The receiver of claim 7, wherein the message is associated with the information bits and cyclic redundancy check (CRC) bits associated with the information bits, and
wherein a concatenation of the information bits and the CRC bits is segmented into the multiple sub-payload blocks.

9. The receiver of claim 8, wherein the CRC bits include a first set of CRC bits associated with a first-stage-decoding-check operation and a second set of CRC bits associated with a second-stage-decoding-check operation.

10. The receiver of claim 9, wherein the processing system is configured to cause the receiver to communicate, with the transmitter, configuration information indicating a quantity of bits associated with the first set of CRC bits.

11. The receiver of claim 9, wherein the processing system, to cause the receiver to decode the message, is configured to cause the receiver to:
determine, for each sub-payload block, of the multiple sub-payload blocks, one or more sub-payload-block hypotheses;
determine multiple payload-block hypotheses, each payload-load hypothesis, of the multiple payload-block hypotheses, including a concatenation of selected sub-payload-block hypotheses;
perform the first-stage-decoding-check operation on the multiple payload-block hypotheses using the first set of CRC bits; and
perform the second-stage-decoding-check operation on a selected payload-block hypothesis, of the multiple payload-block hypotheses, using the second set of CRC bits, wherein the selected payload-block hypothesis is selected based at least in part on performing the first-stage-decoding-check operation.

12. The receiver of claim 7, wherein the payload block is segmented into the multiple sub-payload blocks such that, for each sub-payload block, of the multiple sub-payload blocks:
a portion of information bits from a beginning portion of that sub-payload block is copied, resulting in a copied portion of information bits; and
the copied portion of information bits is concatenated to an end portion of that sub-payload block.

13. The receiver of claim 12, wherein the processing system is configured to cause the receiver to communicate, with the transmitter, configuration information indicating a quantity of bits associated with the portion of information bits.

14. The receiver of claim 12, wherein the processing system, to cause the receiver to decode the message, is configured to cause the receiver to:
determine, for each sub-payload block, of the multiple sub-payload blocks:
one or more sub-payload-block hypotheses, and
a subset of the one or more sub-payload-block hypotheses that pass a check associated with the copied portion of information bits; and
decode the message based at least in part on using the subset of the one or more sub-payload-block hypotheses associated with each sub-payload block.

15. A method of wireless communication performed by a transmitter, comprising:
segmenting a payload block into multiple sub-payload blocks;
independently encoding each sub-payload block, of the multiple sub-payload blocks, using a spinal code encoding scheme, resulting in multiple vectors of spinal symbols;
combining the multiple vectors of spinal symbols, resulting in a transmission vector; and
transmitting, to a receiver, a message indicating the transmission vector.

16. The method of claim 15, further comprising:
determining, using information bits of the payload block, cyclic redundancy check (CRC) bits for the payload block,
wherein segmenting the payload block into the multiple sub-payload blocks includes segmenting a concatenation of the information bits and the CRC bits into the multiple sub-payload blocks.

17. The method of claim 16, wherein the CRC bits include a first set of CRC bits associated with a first-stage-decoding-check operation and a second set of CRC bits associated with a second-stage-decoding-check operation.

18. The method of claim 17, further comprising communicating, with the receiver, configuration information indicating a quantity of bits associated with the first set of CRC bits.

19. The method of claim 15, wherein segmenting the payload block into the multiple sub-payload blocks includes, for each sub-payload block, of the multiple sub-payload blocks:
copying a portion of information bits from a beginning portion of that sub-payload block, resulting in a copied portion of information bits; and
concatenating the copied portion of information bits to an end portion of that sub-payload block.

20. The method of claim 19, further comprising communicating, with the receiver, configuration information indicating a quantity of bits associated with the portion of information bits.
